(19) United States
(12) Patent Application Publication
(10) Pub. No.: US 2018/0220552 A1
(43) Pub. Date: Aug. 2, 2018

(54) MODULAR PROCESSING FACILITY WITH DISTRIBUTED COOLING SYSTEMS

(71) Applicant: Fluor Technologies Corporation, Sugar Land, TX (US)

(72) Inventors: Srinivas Arcot, Calgary (CA); Fred Haney, Calgary (CA); Gary Donovan, Canmore (CA); Todd Roth, Calgary (CA); Alan Lowrie, Calgary (CA); George Morlidge, Okotoks (CA); Simon Lucchini, Calgary (CA); Sean Halvorsen, Calgary (CA)

(21) Appl. No.: 15/420,965

(22) Filed: Jan. 31, 2017

(51) Int. Cl. H05K 7/20; F28D 15/00; F28C 1/00; F28D 15/02

(52) U.S. Cl. CPC H05K 7/20281; F28D 15/00; F28C 1/00; H05K 7/20309; H05K 7/20272; H05K 7/20263; F28D 15/02

(57) ABSTRACT

A processing facility, including a first process block configured to carry out a first process. The first process block includes a plurality of first modules fluidly coupled to one another, and a first cooling system configured to circulate a first cooling fluid within the first process block. In addition, the processing facility includes a second process block configured to carry out a second process that is different from the first process. The second process block includes a plurality of second modules fluidly coupled to one another, and a second cooling system configured to circulate a second cooling fluid within the second process block.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A MICROFICHE APPENDIX

Not applicable.

### TECHNICAL FIELD

This disclosure is generally related to modular construction of process facilities with distributed modular cooling systems incorporated therein.

### BACKGROUND

Building large-scale processing facilities can be extraordinarily challenging in remote locations, or under adverse conditions. One particular geography that is both remote and suffers from severe adverse conditions includes the land comprising the western provinces of Canada, where several companies are now trying to establish processing plants for removing oil from oil sands.

Given the difficulties of building a facility entirely on-site, there has been considerable interest in what shall be referred to herein as 2nd Generation Modular Construction. In that technology, a facility is logically segmented into truckable modules, the modules are constructed in an established industrial area, trucked or airlifted to the plant site, and then coupled together at the plant site. Typically such 2nd Generation (“2nd Gen”) modules are not process based, but rather are equipment based, meaning that each of the modules in a 2nd Gen Construction typically relate to a specific equipment type (e.g., pumps, compressors, heat exchangers, cooling towers, etc.). Several 2nd Gen Modular Construction facilities are in place in the tar sands of Alberta, Canada, and they have been proved to provide numerous advantages in terms of speed of deployment, construction work quality, reduction in safety risks, and overall project cost. There is even an example of a Modular Helium Reactor (MHR), described in a paper by Dr. Arkal Shenoy and Dr. Alexander Telengator, General Atomics, 3550 General Atomics Court, San Diego, Calif. 92121.

2nd Gen Modular facilities have also been described in the patent literatures. An example of a large capacity oil refinery composed of multiple, self-contained, interconnected, modular refining units is described in WO 03/031012 to Shumway. A generic 2nd Gen Modular facility is described in US20080127662 to Stanfield.

Unless otherwise expressly indicated herein, Shumway, Stanfield, and all other extrinsic materials discussed herein are incorporated by reference in their entirety. Where a definition or use of a term in an incorporated reference is inconsistent with or contrary to the definition and/or usage of that term provided herein, the definition or usage of that term provided herein applies, and the definition of that term in the reference does not apply.

There have been cost savings in using 2nd Gen Modular approaches. Nevertheless, despite the many advantages of 2nd Gen Modular Construction, there are still problems. Possibly the most serious problems arise from the ways in which the various modules are inter-connected. In 2nd Gen Modular units, the fluid, power, and control lines between modules are carried by external piperacks. This can be seen clearly in FIGS. 1 and 2 of WO 03/031012. In facilities using multiple, self-contained, substantially identical production units, it is logically simple to operate those units in parallel, and to provide in feed (inflow) and product (outflow) lines along an external piperack. However, where small production units are impractical or uneconomical, the use of external piperacks is a hindrance. For example, not only does the 2nd Gen usage of one or more external piperacks typically result in the utilization of more piping and additional work in the field to interconnect modules, external piperacks interconnecting modules may also typically severely limit the amount of pre-commissioning, check out, and/or commissioning of modules individually and/or before they are installed at the ultimate site of the facility (e.g. at a construction facility in an industrial area remote from the ultimate site of the entire process facility). This limitation typically arises due to the equipment-based nature of 2nd Gen modules as described above, which does not lend itself to stand-alone pre-commissioning, check-out, and/or commissioning (because in order for a process to be performed using such equipment-based 2nd Gen modules, the modules would have to be interconnected with other modules in a way that forms a process which can be evaluated effectively as a whole). This may also especially be true since typical 2nd Gen modules do not have integrated and distributed electrical and instrumentation (E+I) systems and/or cooling systems in each module, but instead typically are connected to a centralized E+I system and/or cooling system (e.g., via home run interconnecting cabling and/or large bore piping run throughout the processing facility within traditional interconnecting racks, etc.).

What is needed is a new modular paradigm, in which the various processes of a plant are segmented in process blocks each comprising one or more (typically multiple) modules. This document refers to such designs and implementations as 3rd Generation (“3rd Gen”) Modular Construction or as 3rd Gen processing facilities.

### SUMMARY

The disclosed subject matter provides apparatus, systems, and methods in which the various processes of a plant are segmented into process blocks, each process block comprising one or more (typically multiple) modules, wherein at least some of the modules within at least some of the process blocks are fluidly and electrically coupled to at least another of the modules using direct-module-to-module connections.

Some embodiments disclosed herein are directed to a processing facility, including a first process block configured to carry out a first process. The first process block includes a plurality of first modules fluidly coupled to one another, and a first cooling system configured to circulate a first cooling fluid within the first process block. In addition, the processing facility includes a second process block configured to carry out a second process that is different from the first process. The second process block includes a plurality of second modules fluidly coupled to one another, and a second cooling system configured to circulate a second cooling fluid within the second process block. Additionally, the first cooling system has a first heat dissipation rate, the second cooling system has a second heat dissipation rate, and the first heat dissipation rate is different from the second heat dissipation rate.

Other embodiments are disclosed herein directed to a processing facility that includes a first process block configured to carry out a first process. The first process block includes a plurality of first modules fluidly coupled to one another, and a first cooling system configured to circulate a first cooling fluid within the first process block. The first cooling system includes a first plurality of conduits and a first heat exchange device. The first plurality of conduits are configured to circulate fluid between the first heat exchange device and equipment within the first process block. In addition, the processing facility includes a second process block configured to carry out a second process. The second process block includes a plurality of second modules fluidly coupled to one another, and a second cooling system configured to circulate a second cooling fluid within the second process block. The second cooling system including a second plurality of conduits and a second heat exchange device. The second plurality of conduits are configured to circulate fluid between the second heat exchange device and equipment within the second process block. The first plurality of conduits and the second plurality of conduits are entirely disposed within an outer periphery of the first process block and the second process block, respectively, and are not run through an interconnecting piperack.

Still other embodiments disclosed herein are directed to a processing facility including a first process block configured to carry out a first process. The first process block includes a plurality of first modules fluidly coupled to one another, and a first cooling system configured to circulate a first cooling fluid within the first process block. The first cooling system including a first plurality of conduits and a first heat exchange device. The first plurality of conduits are configured to circulate fluid between the first heat exchange device and equipment within the first process block, and the first cooling system has a first heat dissipation rate. In addition, the processing facility includes a second process block configured to carry out a second process that is different from the first process. The second process includes a plurality of second modules fluidly coupled to one another, and a second cooling system configured to circulate a second cooling fluid within the second process block. The second cooling system includes a second plurality of conduits and a second heat exchange device. The second plurality of conduits are configured to circulate fluid between the second heat exchange device and equipment within the second process block. The second cooling system has a second heat dissipation rate that is different from the first heat dissipation rate, and the first plurality of conduits and the second plurality of conduits are not run through an interconnecting piperack.

Various objects, features, aspects and advantages will become more apparent from the following description of exemplary embodiments and accompanying drawing figures.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is a flowchart showing some of the steps involved in a 3rd Gen Construction process.

FIG. 2 is an example of a 3rd Gen Construction process block showing a first level grid and equipment arrangement.

FIG. 3 is a simple 3rd Gen Construction “block” layout.

FIG. 4 is a schematic of three exemplary process blocks (#1, #2 and #3) in an oil separation facility designed for the oil sands region of western Canada.

FIG. 5 is a schematic of a process block module layout elevation view, in which modules C, B and A are on one level, most likely ground level, with a fourth module D disposed atop module C.

FIG. 6 is a schematic of an alternative embodiment of a portion of an oil separation facility in which there are again three process blocks (#1, #2 and #3).

FIG. 7 is a schematic of the oil treating process block #1 of FIG. 3, showing the three modules described above, plus two additional modules disposed in a second story.

FIG. 8 is a schematic of a 3rd Gen Modular facility having four process blocks, each of which has five modules.

FIG. 9 is a schematic of another 3rd Gen Modular facility having a total of six interconnected process blocks.

FIG. 10 is a schematic of a 3rd Gen Modular processing facility having a total of three process blocks, one or more of which having a distributed cooling system.

FIG. 11 is a schematic of a 3rd Gen Modular processing facility having a total of two process blocks, each having a distributed cooling system.

### DETAILED DESCRIPTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

The following brief definition of terms shall apply throughout the application. The term “comprising” means including but not limited to, and should be interpreted in the manner it is typically used in the patent context. The phrases “in one embodiment,” “according to one embodiment,” and the like generally mean that the particular feature, structure, or characteristic following the phrase may be included in at least one embodiment of the present invention, and may be included in more than one embodiment (importantly, such phrases do not necessarily refer to the same embodiment). If the specification describes something as “exemplary” or an “example,” it should be understood that refers to a non-exclusive example. The terms “about” or “approximately” or the like, when used with a number, may mean that specific number, or alternatively, a range in proximity to the specific number, as understood by persons of skill in the art field (for example, +/−10%). If the specification states a component or feature “may,” “can,” “could,” “should,” “would,” “preferably,” “possibly,” “typically,” “optionally,” “for example,” “often,” or “might” (or other such language) be included or have a characteristic, that particular component or feature is not required to be included or to have the characteristic. Such component or feature may be optionally included in some embodiments, or it may be excluded. The terms “commissioning” and “pre-commissioning” refer to processes and procedures for bringing a system, component, module, process block, piece(s) of equipment, etc. into working condition. These terms may include testing to verify the function of a given system, component, module, process block, piece(s) of equipment, according to the design specifications and objectives. The term “process” is used herein in the manner that one of ordinary skill (i.e., a process engineer) would use the term for individual processes in a process block layout of a processing facility. In addition, a process carried out within a process block may include one or more “unit operations” which include a physical change and/or chemical transformation in a given process flow (e.g., fluid or solid flow).

Typically, embodiments of a 3rd Gen processing facility would be constructed (for example modularly) by coupling together at least two process blocks. In some embodiments, a processing facility might be constructed at least in part by coupling together three or more process blocks. In some embodiments, each of at least two of the blocks comprises at least two truckable modules, and more preferably three, four, five, or even more such modules. Contemplated embodiments can be rather large, and can have four, five, ten, or even twenty or more process blocks, which collectively might comprise up to a hundred, two hundred, or even a higher number of truckable modules in some embodiments. Other embodiments may have process blocks comprising one or more transportable modules. All manner of industrial processing facilities are contemplated, including nuclear, gas-fired, coal-fired, or other energy producing facilities, chemical plants, and mechanical plants. And while 3rd Gen techniques might be used for some off-shore modular construction, more often 3rd Gen modules and construction techniques would be used to construct on-shore processing facilities.

Unless the context dictates the contrary, all ranges set forth herein should be interpreted as being inclusive of their endpoints, and open-ended ranges should be interpreted to include only commercially practical values. Similarly, all lists of values should be considered as inclusive of intermediate values unless the context indicates the contrary.

As used herein the term “process block” means a part of a processing facility that has several process systems within a distinct geographical boundary. Typically, each process block is configured to achieve a single (stand-alone) process, for example of the sort that a process engineer might use in a process block layout. Thus, the term “process” in this context is utilized in the manner that one of ordinary skill (e.g., a process engineer) would use the term for individual processes in a process block layout of a processing facility. A process carried out within a process block may include one or more unit operations (e.g., a physical change and/or chemical transformation), and typically a process block might comprise two or more unit operations. So in at least some embodiments, a process block includes multiple pieces and types of equipment (e.g., pumps, compressors, vessels, heat exchangers, vessels, coolers, blowers, reactors, etc., for example) for carrying out a plurality of unit operations with a contiguous, defined geographical area (i.e., the geographical area defined by the corresponding process block). In addition, in at least some embodiments the process blocks (e.g. the multiple pieces and types of equipment as well as the multiple unit operations) would be arranged and designed to support or relate to at least one common, overarching process, for example relating to the primary process flow of the production facility as a whole. Typically, each process block would have its own self-supporting E+I and distributed cooling system. Due to such features, each process block may be operable or configured for independent pre-commissioning, check-out, and/or commissioning. Each process block typically accepts specific feed(s) and processes such feed(s) into one or more products (e.g. outputs). In some instances, one or more of the feed(s) for a specific process block may be provided from other process blocks(s) (e.g. the products from one or more other interconnected process blocks) in the facility, and in some instances the products from a specific process block might serve as inputs or feeds into one or more other process blocks of a facility. In the hydrocarbon and chemical business, a process block can comprise equipment, such as processing columns, reactors, vessels, drums, tanks, filters, as well as pumps or compressors to move the fluids through the processing equipment and heat exchangers and heaters for heat transfer to or from the fluid. The type and arrangement of equipment within the defined geographic area of a given process block is designed to carry out the specific process(es) with the feed for that process block (i.e., the equipment arranged within the process bock is chosen and arranged to facilitate the designed process(es) of the process block and is not simply grouped by equipment type such as would be found in a 2nd Gen modular construction). A process block typically might inherently have a series of piping systems and controls to interconnect the equipment within the process block. By eliminating the traditional interconnecting piperack, the 3rd Gen approach may facilitate an efficient systems-based layout resulting in the reduction of piping quantities. For solid material processing facilities, such as mineral processing, the piping systems described above would typically be replaced with material handling equipment (e.g., conveyors, belts, elevators, etc.). Most often, a process block would include a maximum of 20 to 30 pieces of equipment, but there could be more or less pieces of equipment in some process block embodiments. Typically, all equipment for a specific process would be located within a single (for example, contiguous) geographic footprint and/or envelope. Thus, the inputs/feeds for a specific process block would typically be the inputs needed for the process (as a whole), and the outputs for the process block would typically be the outputs resulting from the process (as a whole). Thus, the actual process would basically be self-contained within the corresponding process block. And typically, each such process block is configured to achieve a distinct/different process (which may include one or more unit operations as previously described). While some process facilities might comprise only two process blocks, more typical process facilities may comprise at least 3 process blocks (and in some embodiments, at least 5, at least 7, or at least 10 process blocks), with each of the at least 3 process blocks being non-identical (e.g. each of the at least 3 process blocks may be configured for a different process) (e.g. not simply multiple, substantially identical modules, for example in parallel). So while there may be some amount of duplication of process blocks (for example, for scaling purposes) in 3rd Gen, it is typically true of 3rd Gen processing facilities that they include at least 3 (or at least 2, at least 5, at least 7, or at least 10) different process modules, which may be interconnected (for example via piping and/or electrically) in forming the entire facility. By way of example, a facility might have one or more process blocks for generation of steam, for distillation, scrubbing, or otherwise separating one material from another, for crushing, grinding, or performing other mechanical operations, for performing chemical reactions with or without the use of catalysts, for cooling, and so forth.

As used herein, the term “truckable module” means a section of a process block that includes multiple pieces of equipment and has a transportation weight between 20,000 Kg and 200,000 Kg. The concept is that a commercially viable subset of truckable modules would be large enough to practically carry the needed equipment and support structures, but would also be suitable for transportation on commercially-used roadways in a relevant geographic area, for a particular time of year. It is contemplated that a typical truckable module for the Western Canada tar sands areas would be between 30,000 Kg and 180,000 Kg, and more preferably between 40,000 Kg and 160,000 Kg. From a dimensions perspective, such modules would typically measure between 15 and 30 meters long, and at least 3 meters high and 3 meters wide, but no more than 35 meters long, 8 meters wide, and 8 meters high. While some embodiments may employ one or more truckable modules, other embodiments may employ one or more transportable modules. Transportable modules are modules (e.g. sections of a process block or an entire process block including multiple pieces of equipment) operable to be transported using one or more means for transport. “Transportable module” is intended to be a broader term than “truckable module,” such that the term typically includes truckable modules, for example, but also includes larger modules that would not be considered truckable. So for example, a transportable module might be at least 30,000 Kg or at least 40,000 Kg. In some embodiments, a transportable module might be up to 6,000,000 Kg, or even more (for example, for very large modules). In some embodiments, a transportable module might be between 30,000 Kg and 6,000,000 Kg, between 30,000 Kg and 500,000 Kg or between 40,000 Kg and 350,000 Kg. From a dimensions perspective, such transportable modules would typically measure at least 15 meters long, at least 3 meters wide, and at least 3 meters high, or in other embodiments at least 15 meters long, at least 4 meters wide, and at least 4 meters high.

Truckable and/or transportable modules may be closed on all sides, and on the top and bottom, but more typically such modules would have at least one open side, and possibly all four open sides, as well as an open top. The open sides allow modules to be positioned adjacent to one another at the open sides, thus creating a large open space, comprising 2, 3, 4, 5 or even more modules, through which an engineer operator, or other personnel could walk from one module to another, for example within a process block.

A typical truckable and/or transportable module might well include equipment from multiple disciplines, as for example, process and staging equipment, platforms, wiring, instrumentation, and lighting.

One very significant advantage of 3rd Gen Modular Construction is that process blocks are designed to have only a relatively small number of external couplings. In some embodiments, for example, there are at least two process blocks that are fluidly coupled by no more than three (3), four (4), or five (5) fluid lines, excluding utility lines. It is contemplated, however, that there could be two or more process blocks that are coupled by six (6), seven (7), eight (8), nine (9), ten (10), or more fluid lines, excluding utility lines. It is also contemplated that each process block will include its own integrated E+I system such that E+I lines (e.g., cables, wires, etc.) for each process block are routed through the modules of that process block. For fluid, power, and control lines, it is contemplated that a given line coming into a process block will “fan out” to various modules within the process block. The term “fan out” is not meant in a narrow literal sense, but in a broader sense to include situations where, for example, a given fluid line splits into smaller lines that carry a fluid to different parts of the process block through orthogonal, parallel, and other line orientations. In addition, as used herein, “utility lines” refers to lines (e.g., pipes, conduits, tubes, hoses, etc.) for carrying fluids (i.e., liquids and gases) that facilitate the chemical and/or physical processes within one or more process blocks. For example, the fluid carried by a utility line may include air, nitrogen (N₂), oxygen (O₂), water (H₂O), steam, etc. The term “utility line” does not include electrical or instrumentation cables, lines, wires, etc. (e.g., such as would be associated within the E+I system) and does not include the pipes, conduits, tubes, hoses, etc. that are associated with each process blocks distributed cooling system (except for one or more coolant fluid makeup lines as described below).

Process blocks can be assembled in any suitable manner. For example, in some embodiments 3rd Gen process blocks are arranged and interconnected with one another without an external piperack (so for example, the process blocks would not be laid out with a piperack backbone connecting the process modules, as may be fairly typical in 2nd Gen modular design for example). Instead, in these embodiments the 3rd Gen process blocks typically are directly interconnected with one another in accordance with a 3rd Gen Construction block layout, for example. In other words, each of the process blocks typically would be arranged/positioned in proximity (for example, oftentimes abutting) with one or more process blocks with which it interacts (e.g. with inputs and outputs directly interconnecting the process blocks), without intervening external interconnecting piperack(s) and/or process blocks therebetween. While in some embodiments all process blocks might be positioned and/or interconnected in this manner (e.g. in proximity with and direct interconnected with the other process blocks with which it interacts), in some embodiments only some of the process blocks (e.g. 3 or more, 5 or more, 8 or more, or 10 or more process blocks) might be so arranged and/or interconnected (and other process blocks might be arranged and/or interconnected differently). For example, in some embodiments, the process blocks for the primary process flow might all be so positioned and/or interconnected, even though one or more other process blocks might be positioned in such a way as to require interconnection through an unrelated process block. This direct connection between interconnected process blocks may allow for close coupling of the process blocks, for example with each process block abutting one or more other process blocks such that the interconnections therebetween are located within the envelope of those process blocks. It is contemplated, for example, that process blocks can be positioned end-to-end and/or side-to-side and/or above-below one another. Contemplated facilities include those arranged in a matrix of x by y blocks, in which x is at least 2 and y is at least 3. As another example, in other embodiments, the inputs and outputs of at least some of the 3rd Gen process blocks may optionally be coupled via an internal piping spine that runs through at least a portion of the processing facility (and particularly through (e.g. internally within) the corresponding process blocks). The utility lines associated with the 3rd Gen process blocks may also route along the piping spine so as to feed each of the process blocks. In these embodiments (as well as in other embodiments) the E+I lines and the fluid lines interconnecting the equipment within each process block are not routed through the piping spine and are instead routed independently of the piping spine within the process block (i.e., within the geographic area defined by the corresponding process block).

Within each process block, the modules can also be arranged in any suitable manner, although since modules are likely much longer than they are wide (in some embodiments), some process blocks have 3 or 4 modules arranged in a side-by-side fashion, and abutted at one or both of their collective ends by the sides of one or more other modules. Individual process blocks can certainly have different numbers of modules, and for example a first process block could have five (5) modules, another process block could have two (2) modules, and a third process block could have another two (2) modules. In other embodiments, a first process block could have at least five (5) modules, another process block could have at least another five (5) modules, and a third process block could have at least another five (5) modules.

In some contemplated embodiments, 3rd Gen Modular Construction facilities are those in which the process blocks collectively include equipment configured to extract oil from oil sands. Facilities are also contemplated in which at least one of the process blocks produces power used by at least another one of the process blocks, and independently wherein at least one of the process blocks produces steam used by at least another one of the process blocks, and independently wherein at least one of the process blocks includes an at least two story cooling tower. It is also contemplated that at least one of the process blocks includes a personnel control area, which is controllably coupled to the equipment within the at least one process block (e.g., via electrical conductors, fiber optics cables, etc.). In general, but not necessarily in all cases, the process blocks of a 3rd Gen Modular facility would collectively include at least one of a vessel, a compressor, a heat exchanger, a pump, and/or a filter.

Although a 3rd Gen Modular facility might have one or more piperacks to interconnect modules within a process block, it is not necessary to do so. Thus, it is contemplated that a modular building system could comprise A, B, and C modules juxtaposed in a side-to-side fashion, each of the modules having (a) a height greater than 4 meters and a width greater than 4 meters, and (b) at least one open side; and a first fluid line coupling the A and B modules; a second fluid line coupling the B and C modules; and wherein the first and second fluid lines do not pass through a common interconnecting piperack.

In one aspect of exemplary embodiments, the modular building system would further comprise a first command line coupling the A and B modules; a second command line coupling the B and C modules; and wherein the first and second command lines do not pass through the common piperack. In some embodiments, the A, B, and C modules may comprise at least, 5, at least 8, at least 12, or at least 15 modules. Preferably, at least two of the A, B and C process blocks may be fluidly coupled by no more than five fluid lines, excluding utility lines. In still other embodiments, a D module could be stacked upon the C module, and a third fluid line could directly couple C and D modules.

Methods of laying out a 2nd Gen Modular facility are different in many respects from those used for laying out a 3rd Gen Modular facility. Whereas the former generally merely involves dividing up equipment for a given process or unit operation among various modules (e.g. an equipment-based approach), the latter preferably takes place in a (process-based) five-step process as described below. For example, in a typical 2nd Gen Modular facility, equipment is grouped and arranged by type (e.g., pumps for servicing various different processes are arranged within one or more pumping modules and lines connecting the pumps to the various other pieces of equipment related to the various processes and process blocks are routed through one or more external piperacks). It is contemplated that while traditional 2nd Gen Modular Construction can prefab about 50-60% of the work of a complex, multi-process facility, 3rd Gen Modular Construction can prefab up to about 90-95% of the work. 3rd Gen modular construction can also reduce interconnecting piping and/or cabling, (for example, due to the more direct nature of the interconnections and/or the reduced number of inputs/outputs for each process block) as well as reducing time in the field needed to interconnect modules. The reduction in the length/amount of piping and/or cabling may result in lower total installed costs (TIC) and/or lower operating hydraulic power demand (with respect to piping) and/or lower operating power demand (with respect to cabling). Furthermore, the process-based nature of 3rd Gen construction may allow for much more substantial pre-commissioning, check-out, and/or commissioning (for example at the fab or mod yard, at a location away from the ultimate site of the facility—e.g. off-site), thereby reducing effort and time in the field to complete any additional pre-commissioning, check-out, and/or commissioning of process blocks and their systems. By way of example, each process block of a facility might be fully pre-commissioned, checked-out, and/or commissioned off-site, such that the only pre-commissioning, check-out, and/or commissioning left for the field would be interconnections between process blocks and/or the process facility as a whole.

Also, in at least some embodiments, each process block in a 3rd Gen processing facility disclosed herein includes its own independent (e.g. self-supporting) power and control (i.e., E+I) systems such that the various process blocks in the 3rd Gen facility do not share E+I systems. As a result, each process block may be independently installed and operated without needing to install other process blocks making up the processing facility. In addition, the independent E+I systems for each process block allow for the avoidance of routing E+I lines through an external piperack extending through the processing facility. Typically speaking, in a 2nd Gen facility, a single E+I system is shared and distributed among all modules such that a relatively large amount of E+I lines (e.g., cabling) must be routed between the control station, room, etc. and the various pieces of equipment within each module. Thus, such a typical 2nd Gen arrangement typically requires running the shared E+I lines through one or more external piperacks extending throughout the facility (which is clearly different than 3rd Gen).

In some embodiments, each process block in a 3rd Gen processing facility may include its own independent (e.g., self-supporting) cooling system (also referred to herein as a distributed cooling systems) wherein each cooling system is configured to circulate one or more cooling fluids (e.g., liquid, gas, etc.) throughout the corresponding process block to facilitate cooling of a main process fluid through the process block and/or cooling of one or more auxiliary fluids that are contained and/or routed within the corresponding process block and facilitate the overall processing of the main process fluid(s).

Each cooling system may include one or more heat exchange devices configured to exchange heat within the one or more cooling fluids and another fluid (e.g., the surrounding atmosphere). For example, the one or more heat exchange devices of each cooling system may include water cooling towers, heat exchangers (e.g., shell and tube, plate and frame, etc.), radiators, open pits or tanks, fins, evaporators, or some combination thereof. The heat exchange devices of each cooling system may be disposed within a single module of a process block or, alternatively, may be spread out among more than one or each of the modules of a given process block. In some embodiments, the one or more heat exchange devices of each cooling system may be disposed along a peripheral edge (i.e., along a border edge) of the corresponding process block and/or module or may be disposed along a top or ceiling portion of the corresponding process block and/or module (i.e., such that the one or more heat exchange devices are disposed vertically above other portions of the corresponding process block and/or modules. Without being limited to this or any other theory, placement of the one or more heat exchange devices along a peripheral edge or top portion of a process block and/or module allows the heat exchange device(s) to have greater access to the air of the surrounding environment, therefore promoting more efficient heat transfer between the heat exchange device and the surrounding environment. Alternatively, one or more of the heat exchange devices may be configured to exchange heat from the circulated cooling fluid to another fluid that is not part of the surrounding air (e.g., such as with a local body of water).

Because each process block of a 3rd Gen processing facility (or at least some process blocks) includes its own independent cooling system, maintenance or failures of a process block or its cooling system do not require the shutdown of the cooling systems of other, even adjacent process blocks, such that those process blocks may continue to operate as normal. Moreover, because each process block includes its own cooling system, loss of containment in one cooling system for a given process block (e.g., due to a leak in a pipe or other flow conduit or a trip of a pump or compressor) only results in a relatively small fraction of the typical amount of fluid leaked to the surrounding environment that would typically be the case for a large, centralized cooling system for an entire processing facility. As a result, in at least some embodiments, use of distributed cooling systems within a 3rd Gen modular processing facility offers the potential to reduce the monetary loses and potential environmental damage associated with such a cooling system failure.

In addition, independent, distributed cooling systems of 3rd Gen processing facilities as described herein may be tailor designed to fit the cooling needs of that process block. In a conventional facility, which employs a single, centralized cooling system, a single cooling fluid loop is utilized to provide cooling fluid to multiple different units and/or facilities. As a result, the centralized cooling system must be designed to provide adequate cooling to all units served thereby. This construction scheme often requires that the cooling system be more robust/substantial than is necessary for many (if not most) of the units served by the cooling system. As a result, a large amount of energy is typically spent operating a cooling system to provide cooling fluid at temperature and/or volumes that are above and beyond that needed by many of the individual processing units. By contrast, in a distributed cooling system arrangement as is found in a 3rd Gen modular facility as described herein, each cooling system may be designed to fit to cooling needs of each process block. As a result, the amount of energy required to operate the cooling systems of a 3rd Gen processing facility may be reduced so that the overall energy efficiency of the 3rd Gen processing facility may be increased.

Further, as a part of tailoring the distributed cooling systems to the cooling needs of the corresponding process blocks, in at least some embodiments, cooling systems of different process blocks may circulate a different cooling fluid (or coolant fluid), may have different heat dissipation rates, and/or may utilize different cooling systems types, etc. For example a cooling system of a first process block of a given processing facility may circulate a first cooling fluid, and a cooling system of a second process block of the processing facility may circulate a second cooling fluid that is different from the first cooling fluid. The first cooling fluid and the second cooling fluid may comprise different selections of water, glycol, oil, air or other gases, a refrigerant, etc. in some embodiments.

As another example, a cooling system of a first process block of a given processing facility may utilize an evaporative style cooling system, and a cooling system of a second process block of the processing facility may utilize a dry cooling system. As used herein, an evaporative style cooling system refers to a cooling system that exchanges heat with the surrounding environment through the process of evaporation (e.g., evaporation of the cooling fluid itself or some other fluid), and a dry cooling system refers to heat exchange with cooling media and air or process media with air. In some embodiments, cooling systems of process blocks within a given modular processing facility may include a selection of an evaporative cooling system, a refrigeration cycle cooling system, a dry cooling system, etc. As a result, the cooling systems of the process blocks of a given 3rd Gen modular processing facility may employ different heat exchange devices to facilitate the heat transfer with the surrounding environment (and/or other fluid). For example, a cooling system of a first process block may include a cooling tower (e.g., a water cooling tower) to exchange heat between the circulated cooling fluid and the surrounding environment, whereas a cooling system of a second process block may include a fin-fan cooler to exchange heat between the circulated cooling fluid and the surrounding environment.

As still another example, a cooling system of a first process block of a given processing facility may dissipate heat at a first dissipation rate, and a second cooling system of a second process block of the processing facility may dissipate heat at a second heat dissipation rate that is different from the first heat dissipation rate. Specifically, in some embodiments, a cooling system of a first process block may have a heat dissipation rate of 5 MW, and a cooling system of a second process block may have a heat dissipation rate of 90 MW.

In some embodiments, it may be desirable to circulate the cooling fluid of each specific cooling system at different pressure and/or temperature ranges as required by the processes conducted within the corresponding process blocks. For example, in some embodiments, it is desirable to pressurize a circulated cooling fluid to a pressure greater than a pressure of the process fluid routed within a given process block. Thus, for area(s) where the cooling fluid interacts or exchanges heat with the process fluid, a leak or rupture in a barrier (e.g., a pipe, vessel, etc.) between the cooling fluid and process fluid may allow for a leakage of cooling fluid into the process fluid rather than a leak of the process fluid into the cooling fluid. To accomplish this desired leak path in a conventional, centralized cooling system, the pressure of the cooling fluid is necessarily set to be lower than the process fluid within the process facility overall. However, in the event of a rupture of leak this often results in an over pressurization or contamination of the cooling fluid for many portions of the processing facility (which may circulate a process fluid at different pressures throughout the facility). However, for 3rd Gen modular processing facilities employing distributed cooling systems as described herein, each cooling system may circulate a cooling fluid at a pressure that is appropriate for the process fluid(s) that are flowing within the corresponding process block. For instance, in some embodiments a first process block, having a first cooling system, circulates a process fluid to be cooled at a first pressure, and a second process block, having a second cooling system, circulates another (or the same) process fluid to be cooled at a second pressure (the second pressure being different than the first pressure). In these embodiments, the first cooling system may circulate a first cooling fluid at a third pressure that is greater than the first pressure, and the second cooling system may circulate a second cooling fluid at a fourth pressure that is greater than the second pressure. The temperature range of the cooling media for each process block may be individually selected to suit the cooling needs of the specific processes in each process block and/or by the ability to exchange heat with the environment. Because the first cooling system and the second cooling systems are tailored for the first process block and the second process block, respectively, the third pressure may be different than the fourth pressure and the third and fourth pressures may be optimally set to accomplish the desired leak paths within the first and second process blocks, respectively, without over pressurizing either the first cooling fluid or the second cooling fluid beyond that necessary for these purposes.

In centralized cooling systems for a conventional processing facility, relatively large amounts of cooling fluid must be circulated to provide adequate cooling to each portion or unit of the processing facility. As a result, such a centralized cooling system typically employs relatively large diameter piping, which may have an inner diameter on the order of feet (e.g., approximately 36″ or 3′ in some cases), to accommodate the desired volumetric flow rates of cooling fluid. Such large diameter piping is heavy, expensive, and therefore contributes to the costs and complexity of building, operating, and maintaining a processing facility employing such large diameter piping. Alternatively, a 3rd Gen modular processing facility employing distributed cooling systems as described herein, may include smaller bore piping for routing cooling fluid through the corresponding process block since the volumetric flow rate for each process block specific cooling system may be smaller. In some embodiments, the inner diameter of the piping associated with the cooling system may be on the order of inches rather than feet (e.g., 4″, 6″, 8″, etc.). These smaller piping sizes add significantly less to the overall costs and complexity of construction, maintenance, and operation of the 3rd Gen processing facility than the larger piping sizes disused above.

Additional information for designing 3rd Gen Modular Construction facilities is included in the 3rd Gen Modular Execution Design Guide, which is included in this application. The Design Guide should be interpreted as exemplary of one or more embodiments, and language indicating specifics (e.g. “shall be” or “must be”) should therefore be viewed merely as suggestive of one or more embodiments. Where the Design Guide refers to confidential software, data or other design tools that are not included in this application, such software, data or other design tools are not deemed to be incorporated by reference, but is merely exemplary. In the event there is a discrepancy between the Design Guide and this specification, the specification shall control.

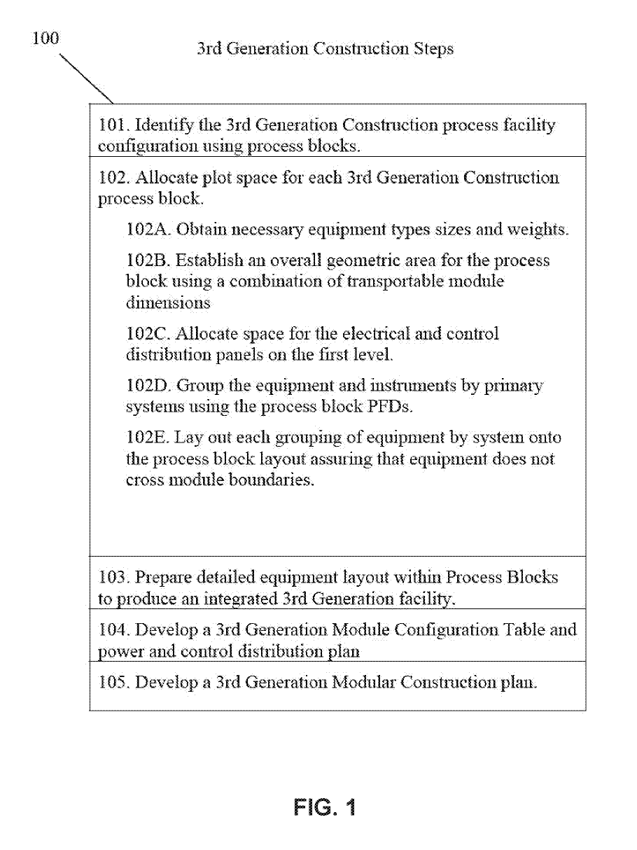

FIG. 1 is a flow chart 100 showing steps in production of a 3rd Generation Construction process facility. In general there are three steps, as discussed below.

Step 101 is to identify the 3rd Gen Construction process facility configuration using process blocks. In this step, the process lead typically separates the facilities into process “blocks”. This is best accomplished by developing a process block flow diagram. Each process block contains a distinct set of process systems. A process block will have one or more feed streams and one or more product streams. The process block will process the feed into different products as shown herein.

Step 102 is to allocate a plot space for each 3rd Gen Construction process block. The plot space allocation typically involves having a piping layout specialist distribute the relevant equipment within each 3rd Gen Construction process block. At this phase of the project, only equipment estimated sizes and weights as provided by process/mechanical need be used to prepare each “block”. A 3rd Gen Construction process block equipment layout involves attention to location to assure effective integration with the piping, electrical and control distribution. In order to provide guidance to the layout specialist the following steps should be followed:

Step 102A is to obtain necessary equipment types, sizes and weights. The equipment should be sized so that it can fit effectively onto a module. Any equipment that has been sized and which cannot fit effectively onto the module envelope should be evaluated by the process lead for possible resizing for effective module installation.

Step 102B is to establish an overall geometric area for the process block using a combination of transportable module dimensions. A first and second level should be identified using a grid layout where the grid identifies each module boundary within the process block.

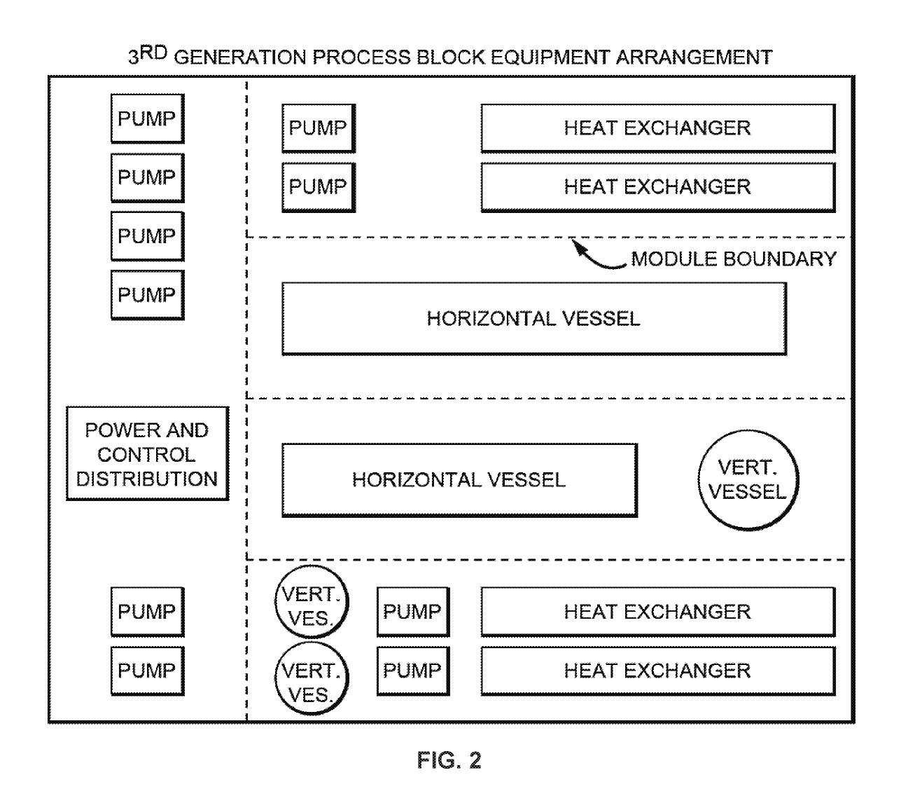

Step 102C is to allocate space for the electrical and control distribution panels on the first level. FIG. 2 is an example of a 3rd Gen Construction process block first level grid and equipment arrangement. The E+I panels are sized to include the motor control centers and distributed instrument controllers and inputs/outputs (I/O) necessary to energize and control the equipment, instrumentation, lighting and electrical heat tracing within the process block. The module which contains the E+I panels is designated the 3rd Gen primary process block module. Refer to E+I installation details for 3rd Gen module designs.

Step 102D is to group the equipment and instruments by primary systems using the process block process flow diagrams (PFDs).

Step 102E is to lay out each grouping of equipment by system (rather than by equipment type) onto the process block layout assuring that equipment does not cross module boundaries. In some embodiments, the layout should focus on keeping the pumps located on the same module grid and level as the E+I distribution panels. This will assist with keeping the electrical power home run cables together. If it is not practical, the second best layout would be to have the pumps or any other motor close to the module with the E+I distribution panels. In addition, equipment should be spaced to assure effective operability, maintainability, and safe access and egress.

The use of Fluor's Optimeyes™ is an effective tool at this stage of the project to assist with process block layouts.

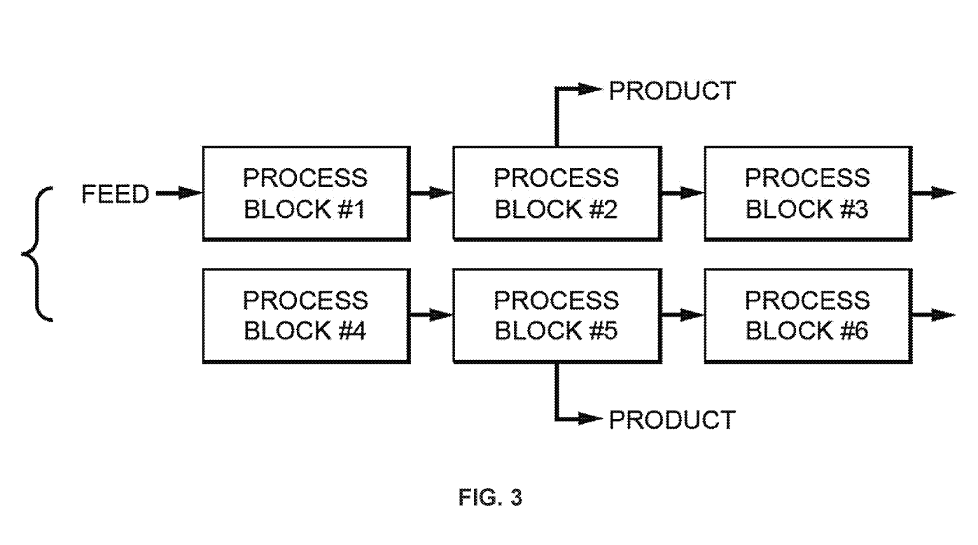

Step 103 is to prepare a detailed equipment layout within process blocks to produce an integrated 3rd Gen facility. Each process block identified from step 102 is laid out onto a plot space assuring interconnects required between blocks are minimized. The primary interconnects are identified from the process flow block diagram. Traditional interconnecting piperacks are preferably no longer needed or used. A simple, typical 3rd Gen “block” layout is illustrated in FIG. 3.

Step 104 is to develop a 3rd Gen Module Configuration Table and power and control distribution plan, which combines process blocks for the overall facility to eliminate traditional interconnecting piperacks and reduce the number of interconnects. A 3rd Gen module configuration table is developed using the above data. Templates can be used, and for example, a 3rd Gen power and control distribution plan can advantageously be prepared using the 3rd Gen power and control distribution architectural template.

Step 105 is to develop a 3rd Gen Modular Construction plan, which includes fully detailed process block modules on an integrated multi-discipline basis. The final step for this phase of a project is to prepare an overall modular 3rd Gen Modular Execution plan, which can be used for setting the baseline to proceed to the next phase. It is contemplated that a 3rd Gen Modular Execution will require a different schedule than traditionally executed modular projects.

Many of the differences between the traditional 1st Generation and 2nd Gen Modular Construction and the 3rd Gen Modular Construction are set forth in Table 1 below, with references to the 3^{rd} Gen Modular Execution Design Guide, which was filed in U.S. Provisional application No. 61/287,956, the entire contents of which being previously incorporated by reference above:

TABLE 1

| Activities | Traditional Truckable Modular Execution | 3^{rd} Gen Modular Execution |
|---|---|---|
| Layout & Module | Steps are: | Utilize structured work process to develop plot layout based |
| Definition | Develop Plot Plan using equipment dimensions and Process Flow | on development of Process Blocks with fully integrated |
| | Diagrams (PFDs). Optimize interconnects between equipment. | equipment, piping, electrical and instrumentation/controls, |
| | Develop module boundaries using Plot Plan and Module | including the following steps: |
| | Transportation Envelope | 1. Identify the 3^{rd} Gen process facility configuration using |
| | Develop detailed module layouts and interconnects between modules | process blocks using PFDs. |
| | and stick-built portions of facilities utilizing a network of | 2. Allocate plot space for each 3^{rd} Gen Process Block. |
| | piperack/sleeperways and misc. supports | 3. Detailed equipment layout within Process Blocks using 3^{rd} |
| | Route electrical and controls cabling through | Gen methodology to eliminate traditional interconnecting |
| | interconnecting racks and misc, supports to connect various loads | piperack and minimize or reduce interconnects within |
| | and instruments with satellite substation and racks. | Process Block modules. The layout builds up the Process |
| | Note: This results in a combination of 1″ generation (piperack) and | Block based on module blocks that conform to the |
| | 2′ generation (piperack with selected equipment) modules that fit the | transportation envelope. |
| | transportation envelope. | 4. Combine Process Blocks for overall facility to eliminate |
| | Ref: Section 1.4A | traditional interconnecting piperacks and reduce number of |
| | | interconnects. |
| | | 5. Develop a 3^{rd} Gen Modular Construction plan, which |
| | | includes fully detailed process block modules on integrated |
| | | multi-discipline basis |
| | | Note: This results in an integrated overall plot layout fully |
| | | built up from Module blocks that conform to the |
| | | transportation envelope. |
| | | Ref: Section 2.2 thru 2.4 |
| Piperacks/ | Modularized piperacks and sleeperways, including cable tray for | Eliminates the traditional modularized piperacks and |
| Sleeperways | field installation of interconnects and home-run cables | sleeperways. Interconnects are integrated into Process Block |
| | Ref: Section 2.5 | modules for shop installation. |
| | | Ref: Section 2.2 |
| Buildings | Multiple standalone pre-engineered and stick built buildings | Buildings are integrated into Process Block modules. |
| | based on discrete equipment housing. | Ref: Section 3.3D |
| Power | Centralized switchgear and MCC at main and satellite | Decentralized MCC & switchgear integrated into |
| Distribution | substations. | Process Blocks located in Primary Process Block |
| Architecture | Individual home run feeders run from satellite substations to | module. |
| | drivers and loads via interconnecting piperacks. | Feeders to loads are directly from decentralized MCCs |
| | Power cabling installed and terminated at site. | and switchgears located in the Process Block without the |
| | | need for interconnecting piperack. |
| | | Power distribution cabling is installed and terminated in |
| | | module shop for Process Block interconnects with pre- |
| | | terminated cable connectors, or coiled at module |
| | | boundary for site interconnection of cross module |
| | | feeders to loads within Process Blocks using pre- |
| | | terminated cable connectors. |
| | | Ref: Section 3.3E |
| Instrument and | Control cabinets are either centralized in satellite substations or | Control cabinets are decentralized and integrated into the |
| Control Systems | randomly distributed throughout process facility. | Primary Process Block module. |
| | Instrument locations are fallout of piping and mechanical layout. | Close coupling of instruments to locate all instruments |
| | Vast majority of instrument cabling and termination is done in | for a system on a single Process Block module to |
| | field for multiple cross module boundaries and stick-built | maximum extent practical. |
| | portions via cable tray or misc. supports installed on | Instrumentation cabling installed and terminated in |
| | interconnecting piperacks. | module shop. |
| | | Process Block module interconnects utilize pre-installed |
| | | cabling pre-coiled at module boundary for site |
| | | connection using pre-terminated cable connectors. |
| | | Ref: Section 3.3F |

A typical 3^{rd} Gen modular processing facility/system might typically include at least 3 (typically modular, such as being formed of one or more transportable modules) process blocks. Although other embodiments could comprise at least 2, at least 5, at least 7, or at least 10 process blocks. The at least 3 process blocks typically would be non-identical process blocks (e.g. each process block configured for a different process and/or having different structure and/or equipment and/or layout). In this way, 3rd Gen modular construction may be quite different from typical 2nd Gen construction approaches, since the 3rd Gen facility typically would not simply be multiple, substantially identical modules, for example in parallel (as may be typical of 2nd Gen modular construction, for example).

Typically, the at least 3 process blocks of an exemplary 3rd Gen facility would each comprise one or more transportable modules (which typically would be configured to jointly achieve the process of the corresponding process block, if the corresponding process block is made up of multiple modules). 3rd Gen modular facilities typically employ a different layout (of modular elements) than conventional 2nd Gen facilities. For example, typically the at least 3 process blocks of an exemplary 3rd Gen modular facility would not be laid out on an (external) piperack backbone for interconnecting process blocks (or modules). In other words, in at least some embodiments there typically would be no external interconnecting piperack between/linking/interconnecting the at least 3 process blocks of such a 3rd Gen facility (for at least the process blocks associated with the primary process fluid flow through the production facility). Instead, the 3rd Gen process blocks would be adjacent one another and directly interconnected (for example, without intervening external piperack or other equipment therebetween). This may mean that in some 3rd Gen embodiments, for example, the interconnections between process blocks would be disposed entirely within an envelope of the process blocks. Thus, interconnections between a first and a second of the at least 3 process blocks of an exemplary 3rd Gen modular facility might be located entirely within the envelopes of the first and second process blocks. Oftentimes, such process blocks would be close coupled to minimize interconnects and/or to reduce overall footprint of the facility (for example, with interconnecting process blocks abutting one another). While there may not be interconnecting external piperack(s) in typical 3rd Gen modular construction, each of the at least 3 process blocks may optionally comprise integral pipeways for utility distribution within the process block (and in some instances for process block interconnects).

Typically, each of the at least 3 process blocks of a 3rd Gen facility would be configured based on a process-based approach or layout (e.g. with each process block configured to achieve a specific stand-alone process, which may be operable to run without accessing equipment from other modules outside the process block (e.g. other than inputs and outputs from the process block as a whole—such that a process block merely takes its inputs, for example, from one or more other process blocks, performs an integral process or unit operation using those inputs, and then provides or emits the outputs from the integral process (for example, to one or more other process blocks))). Each process block typically accepts specific feed(s) and processes such feed(s) into one or more products (e.g. outputs). In some instances, one or more of the feed(s) for a specific process block may be provided from other process blocks(s) (e.g. the products from one or more other interconnected process blocks) in the facility, and in some instances the products from a specific process block might serve as inputs or feeds into one or more other process blocks of a facility. In the hydrocarbon and chemical business, a process block can comprise equipment, such as processing columns, reactors, vessels, drums, tanks, filters, as well as pumps or compressors to move the fluids through the processing equipment and heat exchangers and heaters for heat transfer to or from the fluid. A process block typically might inherently have a series of piping systems and controls to interconnect the equipment within the block. By eliminating the traditional interconnecting piperack, the 3rd Gen approach may facilitate an efficient systems-based layout resulting in the reduction of piping quantities. For solid material processing facilities, such as mineral processing, the piping systems described above would typically be replaced with material handling equipment (e.g., conveyors, belts, etc.). Most often, a process block would include a maximum of 20 to 30 pieces of equipment, but there could be more or less equipment in some process block embodiments. Typically, all equipment for a specific process would be located within a single (for example, contiguous) geographic footprint and/or envelope. Thus, the inputs/feeds for a specific process block would typically be the inputs needed for the process (as a whole), and the outputs for the process block would typically be the outputs resulting from the process (as a whole). Thus, the actual process would basically be self-contained (physically) within the corresponding process block. This may differ from conventional 2nd Gen approaches, which may typically use an equipment-based approach (such that typical 2nd Gen modules may be required to interact with equipment from several modules being needed to perform a specific process). In other words, 3rd Gen process block embodiments may not have an equipment-based approach or layout.

In at least some embodiments of a 3rd Gen modular processing facility, each process block includes multiple pieces and types of equipment for carrying out one or more (e.g., multiple) unit operations within the contiguous geographic region defined by the process block. The unit operations and associated equipment may be arranged to carry out, or relate to one or more common, overarching processes within the 3rd Gen modular processing facility.

In at least some of these embodiments, the equipment disposed within the process block may be grouped by type within a given process block. For example, within a given process block, each of the units or pieces of equipment of one type (e.g., each of the pumps within the process block) may be disposed together within a first defined geographic envelope or space within the overall geographic boundary of the process block and each of the units or pieces of equipment of another type (e.g., each of the heat exchangers within the process block) may be disposed together within a second defined geographic envelope or space within the overall geographic boundary of the process block. Within this example, the first defined region may be separate (e.g., not overlapping) with the second defined region with the given process block. In some embodiments, such geographical grouping of a specific type of equipment may only occur for one type of equipment within the process block (such as E+I equipment, which typically might all be grouped or located together within a process block), or it may occur for multiple (or even all) types of equipment within the process block.

In a typical exemplary 3rd Gen modular processing facility, each of the at least 3 process blocks may comprise its own integral E+I system and distribution (e.g. electrical control and instrument system) in addition to a distributed cooling system (described above). As a result, each process block in a 3rd Gen modular processing facility disclosed herein may include its own integral (e.g. self-supporting) power supply and control systems for operating that process block (and the equipment disposed therein) as well as its own cooling system for circulating a cooling fluid for heat exchange purposes. The distributed E+I system of each process block may eliminate home run interconnecting cabling and fluid flow pipes for centralized cooling systems through traditional interconnecting racks (of the sort which typically may be used in conventional 2nd Gen modular approaches). In addition, this may be beneficial for allowing each process block to operate as a stand-alone process (as described above, for example), and may provide commissioning benefits. So, for example, each of the at least 3 process blocks may be configured to allow for independent pre-commissioning, check-out, and/or commissioning of its corresponding process system (for example, without connection to any other of the at least 3 process blocks). This may allow for separate/independent pre-commissioning, check-out, and/or commissioning of its corresponding process system, for example, at a location geographically separate and apart (e.g. distant) from the ultimate site of the facility (such as a fab or mod yard). The ability to perform separate/independent pre-commissioning, check-out, and/or commissioning for each 3rd Gen process block may be due to integral E+I (within each process block), distributed cooling systems, the process block design approach, and/or lack of external interconnecting piperack (which, for example, may allow for fewer connections which can be more easily connected for simulation and/or testing). Moreover, because of the independent, integral E+I system and distribution and the independent, distributed cooling systems within each process block, as each process block is installed at the production facility, it may be independently operated for its intended function or process while other process blocks are either not yet operational or are not yet even installed (assuming that the operating process block's feed is available and other necessary utility services to the operating process block have been connected and are operating). Such independent operation of process blocks was not available in a 2nd Gen production facility since operation of any one process required the installation of the shared E+I system and distribution and the shared, centralized cooling system to the entire production facility. As a result, the total time to production from a 3rd Gen production facility may be greatly shortened from that typically experienced in a 2nd Gen production facility.

The arrangement/layout of process blocks in exemplary 3rd Gen modular facilities may also be distinct. For example, each of the at least 3 process blocks may be located/arranged in proximity to one or more other of the at least 3 process blocks (e.g. without intervening process blocks, modules, and/or piperacks therebetween). Typically, each of the at least 3 process blocks would be interconnected to one or more other of the at least 3 process blocks (and, for example, the interconnects might include fluid (e.g. piping), solids (e.g., conveyors), etc.). Typically, each of the at least 3 process blocks would be positioned/arranged in proximity to the other of the at least 3 process blocks to which it directly interconnects, for example, without intervening external piperacks and/or process blocks therebetween. While not required in all 3rd Gen embodiments, often the at least 3 process blocks would abut at least one other of the at least 3 process blocks (for example, interconnected process blocks might typically abut one another—for example, forming a contiguous geographic footprint and/or envelope). For such abutting process blocks, interconnections between such process blocks might typically be disposed entirely within the envelope of abutting process blocks. And in some 3rd Gen embodiments, all process blocks might abut the other process blocks to which they interconnect (or at least might directly abut the other process blocks with which it interacts with respect to the primary process flow), such that the facility as a whole might have a contiguous geographic footprint and/or envelope (in which case, all interconnections between process blocks might be within the contiguous envelope of the facility process blocks as a whole (e.g. jointly), such that no external piperacks would be necessary).

Typical process blocks would each have feed input piping (or solid material transfer), product output piping (or solid material transfer), and utility support inputs and outputs. As previously described, utility support inputs and outputs might include one or more one or more inputs for fluid lines (e.g., pipes, conduits, hoses, etc.) that carry fluids (e.g., liquids and/or gases) to support the systems operation within a process block. For example, such liquids and gases carried by the utility pipes include, steam, water, N₂, O₂, air, makeup cooling fluid for the distributed cooling systems, etc. Process blocks would typically be arranged to efficiently interconnect to each other based on the process flow through the facility. Utilities may also be interconnected between process blocks in a similar design for efficient flow.

Each process block may be formed of one or more transportable modules (thereby allowing construction of such modules off-site at locations distant from the final site for the process facility). Typically, each of the transportable modules for the process blocks might be sized as discussed above with respect to transportable modules. And in some embodiments, one or more of the modules might be sized to be truckable, as described above. So, a process block can be formed of (e.g. comprise) one to several modules, for example, depending on the maximum module size and/or weight the local site infrastructure will allow for transport. The use of smaller truckable modules might result in several modules per process block, while the use of VLMs (very large modules) could allow for one module per process block. The modules making up each process block would typically be configured with equipment so that, when interconnected, the modules would jointly perform the process of the corresponding process block (for example, with the equipment in a plurality of related modules for a corresponding process block working together (e.g. interlinked) to accomplish the overall process of the process block). In laying out modules (in forming a corresponding process block), each module would typically be arranged in proximity (typically abutting) with the one or more modules with which it interconnects (e.g. without any intervening external piperack and/or module). So typically, the modules for a process block would not interconnect via a piperack (for example, an interconnecting piperack located external to the modules), but might rather be directly interconnected. And most often, the modules associated with a specific (corresponding) process block would abut to form a contiguous footprint and/or envelope for the process block as a whole. As otherwise described herein, such abutment of modules and/or process blocks may be side-by-side, end-to-end, and/or stacked, for example.

Such 3rd Gen modular process facilities may be constructed uniquely, due to the 3rd Gen nature of the process blocks and/or modules and/or the process-based approach. For example, a typical exemplary 3rd Gen modular method of constructing a processing facility (for example, of the sort described above) might comprise arranging a plurality of process blocks (e.g. at least 3 process blocks) with respect to one another, wherein the at least 3 process blocks are non-identical process blocks (e.g. each configured for a different process) (e.g. not simply multiple, substantially identical modules, for example in parallel), wherein the at least 3 process blocks each comprise one or more transportable modules (which are configured to jointly achieve the process of the corresponding process block); and wherein the at least 3 process blocks are not laid out on an (external) piperack backbone for interconnecting process blocks (or modules) (e.g. no external interconnecting piperack between/linking/interconnecting the 3 process blocks) (e.g. process blocks are directly interconnected (without intervening piperack therebetween, for example, such that the interconnections between process blocks are disposed entirely within an envelope of the process blocks—for example, with interconnections between a first and a second of the at least 3 process blocks being located entirely within the envelopes of the first and second process blocks). Such a method might also and/or further comprise constructing one or more (e.g., each or all) of the at least 3 process blocks at (one or more location) different (remote/away) from the ultimate site of the processing facility (e.g., a fab or mod yard); and pre-commissioning, check-out, and/or commissioning of a corresponding process system for the one or more process blocks constructed away from the ultimate facility site (e.g., at the fab or mod yard) (e.g., without connection to any other of the at least 3 process blocks) (e.g., at a location separate and apart from the ultimate site of the facility, such as a mod yard) (e.g., due to integral E+I and cooling system, process block design approach, and/or lack of external interconnecting piperack). In some embodiments, such methods might further comprise directly interconnecting (e.g. without an external interconnecting piperack) each process block (which might be pre-commissioned, checked out, or commissioned previously) to one or more adjacent process blocks (e.g. without intervening external piperacks and/or other process blocks therebetween). In some such methods, the arrangement of process blocks might also include close coupling one or more (e.g., all) of the at least 3 process blocks (e.g., to reduce overall footprint of the facility and/or reduce/minimize interconnects). Some method embodiments might further comprise designing/configuring each process block to accomplish a corresponding process, which in some embodiments might include laying out equipment in the modules making up each process block accordingly. Also, some method embodiments might further comprise the step of providing integral E+I distribution and a distributed cooling system for each of the at least 3 process blocks (e.g., to eliminate home run interconnecting cabling). The modular nature of 3rd Gen construction may also allow for more efficient construction and/or implementation, for example, using integrated execution to support the modular implementation with reduced scheduling versus traditional/conventional stick build or 2nd Gen (e.g., equipment only modules).

In some embodiments, two or more of the process blocks to be interconnected may not able to be placed adjacent one another such that one or more fluid lines interconnecting the inputs and outputs of the two or more process blocks must be routed through another geographically intervening process block or other equipment. However, this sort of arrangement is not required, and in at least some embodiments, such a routing of the one or more fluid lines does not occur. If such fluid line routing becomes necessary, design efforts (regarding placement of process blocks and/or interconnections between process blocks) would typically seek to minimize this type of indirect routing or interconnection as much as possible (e.g. most process blocks should preferably be directly interconnected and located adjacent to the other process blocks with which it interacts, especially with respect to the primary process flow). So for at least some embodiments, the primary flow (i.e., the primary process flow through the 3rd Gen production facility) would typically flow between adjacent and directly interconnected process blocks. Stated another way, the process blocks in a 3rd Gen production facility that are associated with the main or primary process flow are typically positioned geographically adjacent one another such that each of these process blocks is directly interconnected with no intervening piperacks or other equipment or modules therebetween. So while there may be process blocks in a 3rd Gen facility that are not adjacent and/or interconnected with one or more other process blocks with which it interacts, in a 3rd Gen facility typically at least 3, at least 5, at least 8, or at least 10 process blocks (for example, relating to the main or primary process flow) would be adjacent (or abutting) and/or directly interconnected with the other such of the at least 3, at least 5, at least 9 or at least 10 process blocks with which it interacts.

In addition, in some embodiments, one or more of the fluid lines interconnecting the inputs and outputs of the 3rd Gen process blocks are routed through a central piping spine that runs through at least a portion of the (and in some instances, through the entire) processing facility (and particularly through at least some of the process blocks, with the spine located internally within at least some of the process blocks). In addition, in at least some of these embodiments, the utility lines (e.g., carrying steam, water, air, N₂, O₂, makeup cooling fluid for the distributed cooling systems, etc.) associated with the process blocks may also route along the piping spine so as to access each of the process blocks. In these embodiments (as well as in other embodiments) the E+I lines, fluid lines circulating the cooling fluid within the distributed cooling systems, and the fluid lines interconnecting the equipment within each process block are not routed through the piping spine and are instead routed within each individual process block (i.e., within the geographic area defined by the corresponding process block) as described above. Such an optional spine might serve to line up inputs and outputs for multiple process blocks (for example regarding the primary process flow and/or utilities), thereby optimizing layout of a facility. So, typically such a spine would not be used for equipment connections within a process blocks, but would instead typically be focused on inputs and outputs between interconnected process blocks.

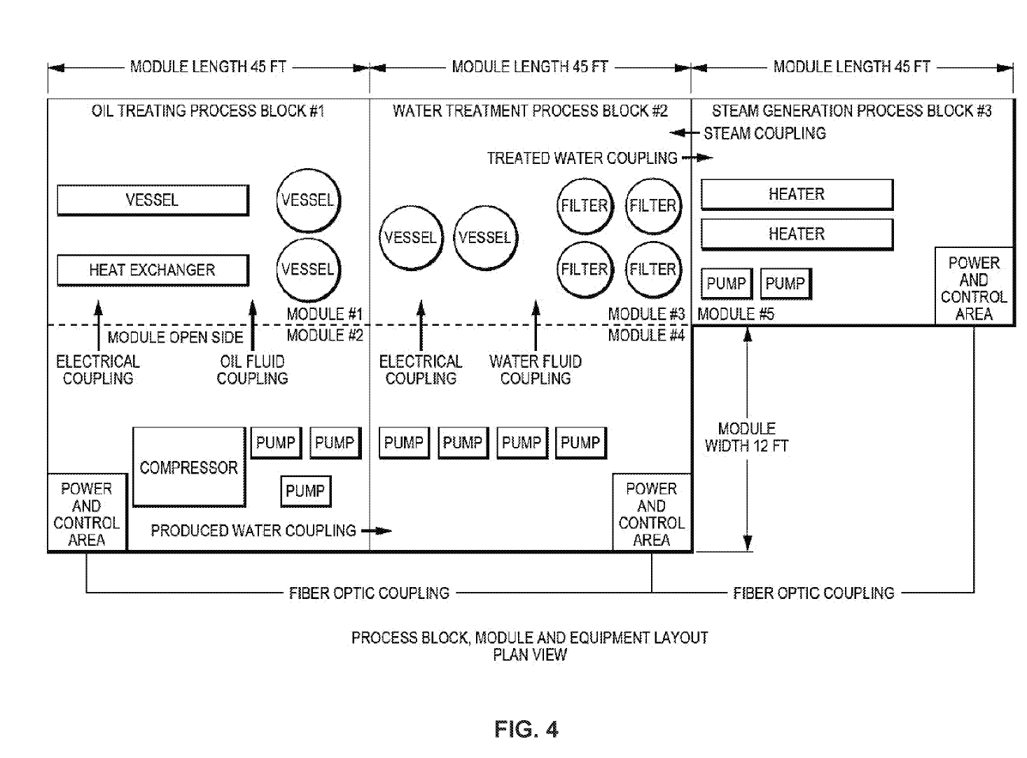

FIG. 4 is a schematic of three exemplary process blocks (#1, #2, and #3) in an oil separation facility designed for the oil sands region of western Canada. Here, process block #1 has two modules (#1 and #2), process block #2 has two modules (#3 and #4), and process block #3 has only one module (#5). The dotted lines between modules indicate open sides of adjacent modules, whereas the solid lines around the modules indicate walls. The arrows show fluid and electrical couplings between modules. Thus, FIG. 4 shows only one electrical line connection and one fluid line connection between modules #1 and #2. Similarly, FIG. 4 shows no electrical line connections between process blocks #1 and #2, and only a single fluid line connection between those process blocks. Further, FIG. 4 shows utility lines (shown as “Steam Coupling” and “Treated Water Coupling”) extending between module #3 of Water treatment process Block #2 and module #5 of Steam Generation Process Block #3.

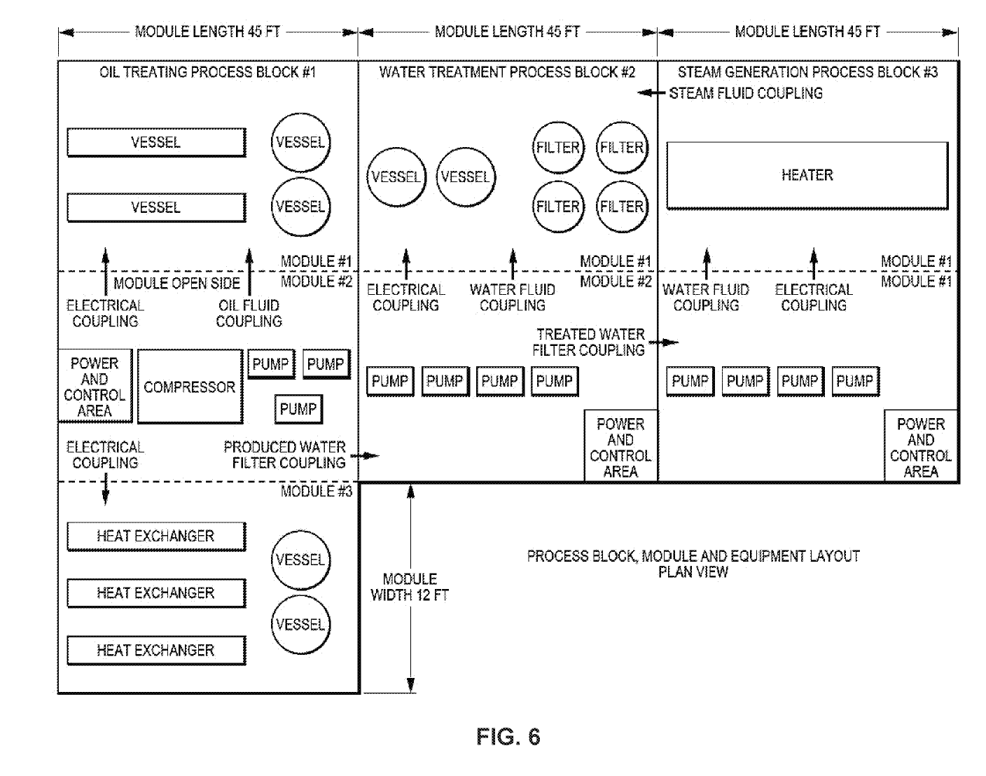

Still further, FIG. 4 shows that each process block (process blocks #1, #2, #3) each have their own Power and Control Area. In at least some embodiments, each Power and Control Area is a designated location (which in some embodiment comprises an enclosure or room, or simply one or more control panels) within the corresponding process block (e.g., process blocks #1, #2, #3) that operating personnel may direct, monitor, initiate, and/or control (collectively “control operations”) the operation of the process block and any and all equipment contained therein. Typically, the integrated E+I system and distribution is coupled to and includes the Power and Control area to facilitate the control operations described above. While FIG. 4 shows a fiber optic coupling extending between each of the Power and Control Areas, it should be appreciated that such a coupling is not required and may not be included in other embodiments (i.e., in some embodiments, the Power and Control Areas of each process block are not coupled to one another—e.g., as shown in FIG. 6).

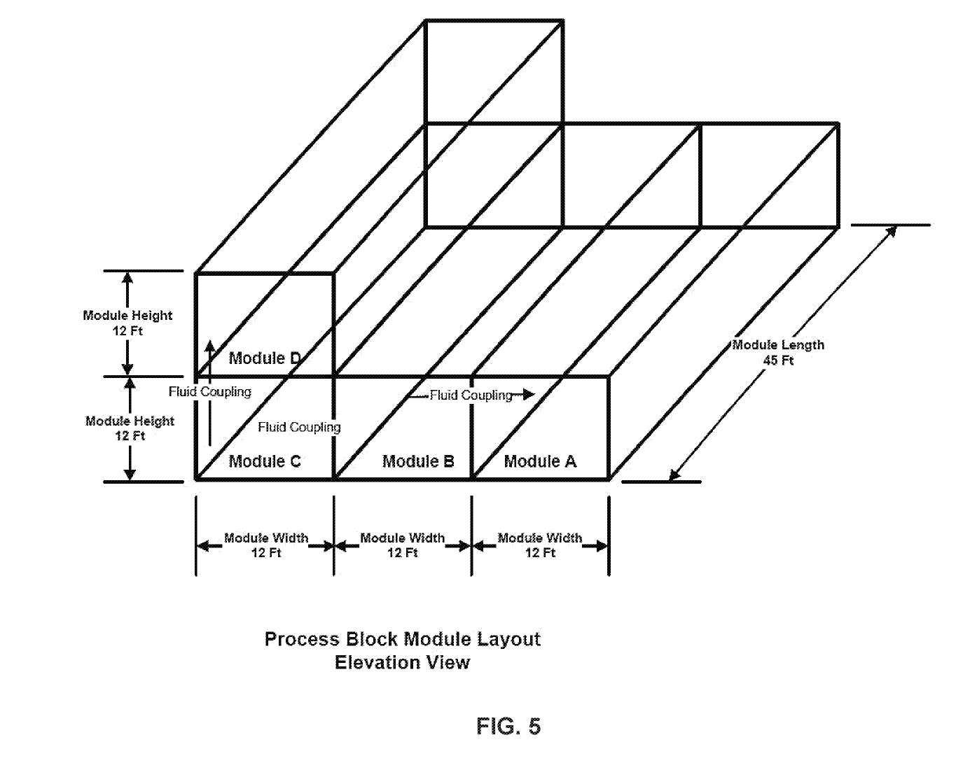

FIG. 5 is a schematic of a process block module layout elevation view, in which modules C, B, and A are on one level, most likely ground level, with a fourth module D disposed atop module C. Although only two fluid couplings are shown, FIG. 5 should be understood to potentially include one or more additional fluid couplings, and one or more electrical and control couplings.

FIG. 6 is a schematic of an alternative embodiment of a portion of an oil separation facility in which there are again three process blocks (#1, #2 and #3). But here, process block #1 has three modules (#1, #2, and #3), process block #2 has two modules (#1 and #2), and process block #3 has two additional modules (#1 and #2). Also, it should be appreciated that each of the Power and Control Areas of process blocks #1, #2, and #3 of FIG. 6 are not coupled or interconnected (e.g., with a fiber optical cable or the like).

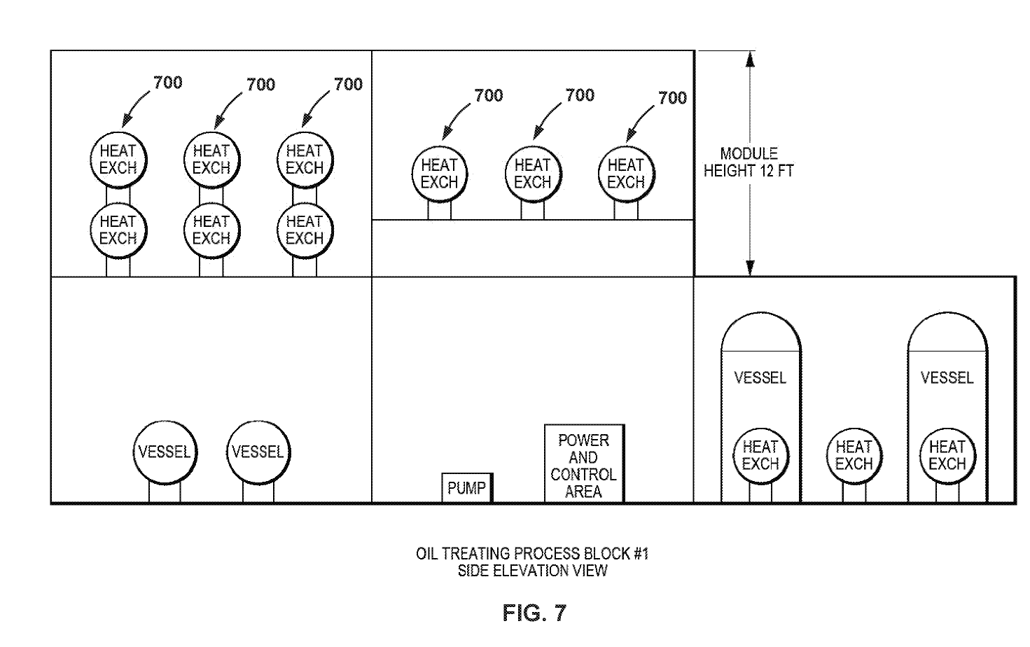

FIG. 7 is a schematic of the oil treating process block #1 of FIG. 3, showing the three modules described above, plus two additional modules disposed in a second story. As previously described above, in some embodiments of a 3rd Gen processing facility, one or more of the process blocks may place the heat exchange device of the corresponding distributed cooling system along a peripheral edge or top surface of the corresponding process block to, for example, maximize exposure of the heat exchangers to the surrounding atmosphere or environment. For example, FIG. 7 shows a plurality of heat exchange devices (shown as generic heat exchangers 700) in a pair of modules that are vertically above other modules within process block #1 in FIG. 7.

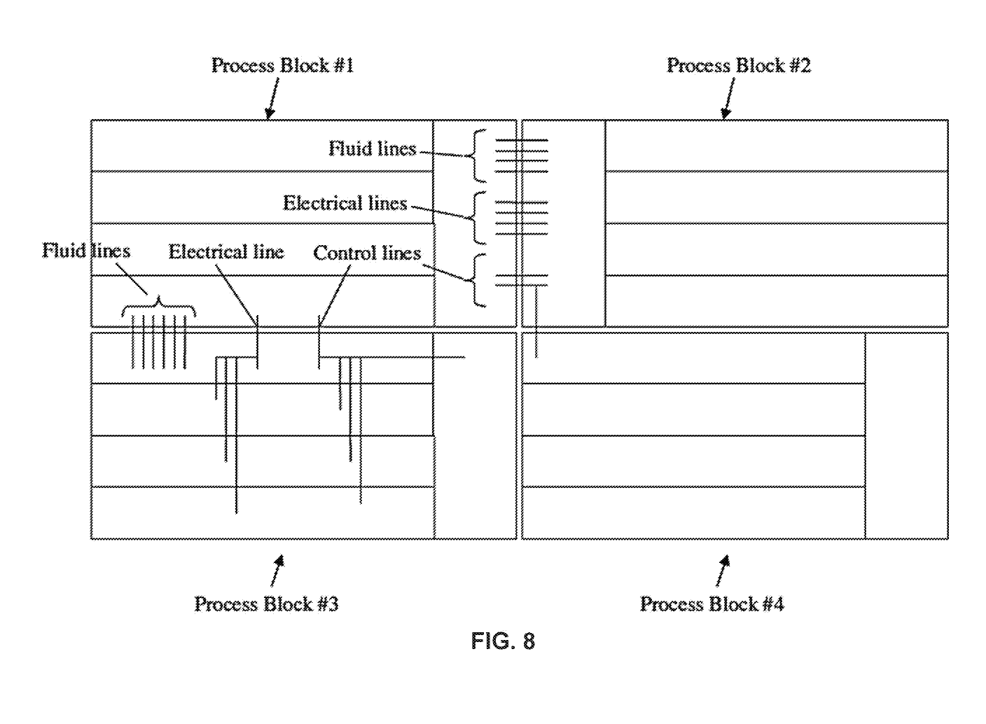

FIG. 8 is a schematic of a 3rd Generation Modular facility having four process blocks, each of which has five modules. Although dimensions are not shown, each of the modules should be interpreted as having (a) a length of at least 15 meters, (b) a height greater than 4 meters, (c) a width greater than 4 meters, and (d) having open sides and/or ends where the modules within a given process block are positioned adjacent to one another. In this particular example, the first and second process blocks are fluidly coupled by no more than four fluid lines, excluding utility lines, four electrical lines, and two control lines. The first and third process blocks are connected by six fluid lines, excluding utility lines, and by one electrical and one control line.

Also in FIG. 8, a primary electrical supply from process block #1 fans out to three of the four modules of process block #3, and a control line from process block #1 fans out to all four of the modules of process block #3.

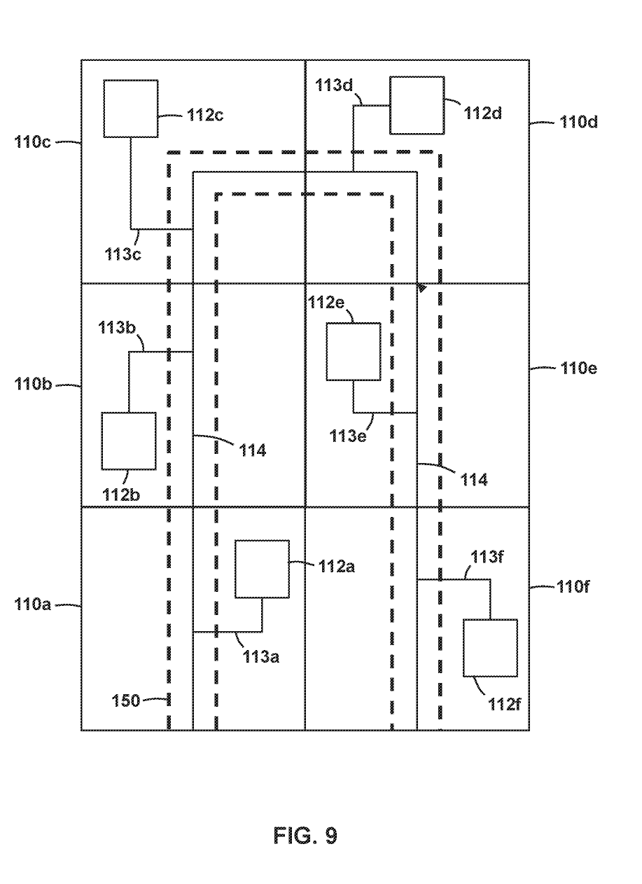

FIG. 9 is a schematic of a 3rd Gen Modular facility having six process blocks 110a-110f. As previously described, in some embodiments, one or more of the utility lines interconnecting the inputs and outputs of the 3rd Gen process blocks are routed through a central piping spine that runs through at least portions of the processing facility (and particularly through and within at least some of the plurality of the process blocks). The embodiment of FIG. 9 shows a piping spine 150 that extends through each of the process blocks 110a-110f of an exemplary 3rd Gen modular facility. In this embodiment, piping spine 150 carries a plurality of utility lines (not specifically shown) that are coupled to the process blocks 110a-110f (and therefore carry various utility fluids to process blocks 110a-110f as previously described above). Further, in the embodiment of FIG. 9, each of the fluid lines (e.g., pipes, conduits, etc.—not shown) interconnecting the equipment within each process block 110a-110f and the E+I lines (also not shown) routed throughout each process block 110a-110f are not routed through the piping spine 150 and are instead routed exclusively within the corresponding process block itself (i.e., within the geographic boundary defined by the corresponding process block 110a-1100, typically in a more direct manner.

In addition, as shown in FIG. 9, in this embodiment, each process block 110a-110f includes its own distributed cooling system 112a-112f, respectively. Each cooling system 112a-112f includes a makeup fluid line 113a-113f, respectively, that supplies makeup fluid to the corresponding cooling system 112a-112f, respectively. Each of the makeup fluid lines 113a-113f are fluidly coupled to a header line 114 routed through the piping spine 150. In embodiments where cooling systems 112a-112f utilize different cooling fluids, there may be more than one such header line (e.g., line 114) routed through piping spine 150 to supply makeup cooling fluid to cooling systems 112a-112f. For the sake of simplicity, the embodiment shown, each of the cooling systems 112a-112f utilize the same type of cooling fluid, such that only a single header line 114 for supplying makeup cooling fluid is shown routed through piping spine 150. Thus, during operation, makeup cooling fluid is supplied to each of the cooling systems 112a-112f to replace cooling fluid that may have been lost, such as, for example, due to evaporation, leaks, flushing, etc. It should be noted that in some embodiments, because each process block is individually designed to carry out a specific processing step(s), the layout of equipment (including any heat exchange devices of the cooling system) is often different from process block to process block. Therefore, in FIG. 9, each cooling system 112a-112f (which may include one or more heat exchange devices) is arranged differently within the corresponding process block 110a-110f.

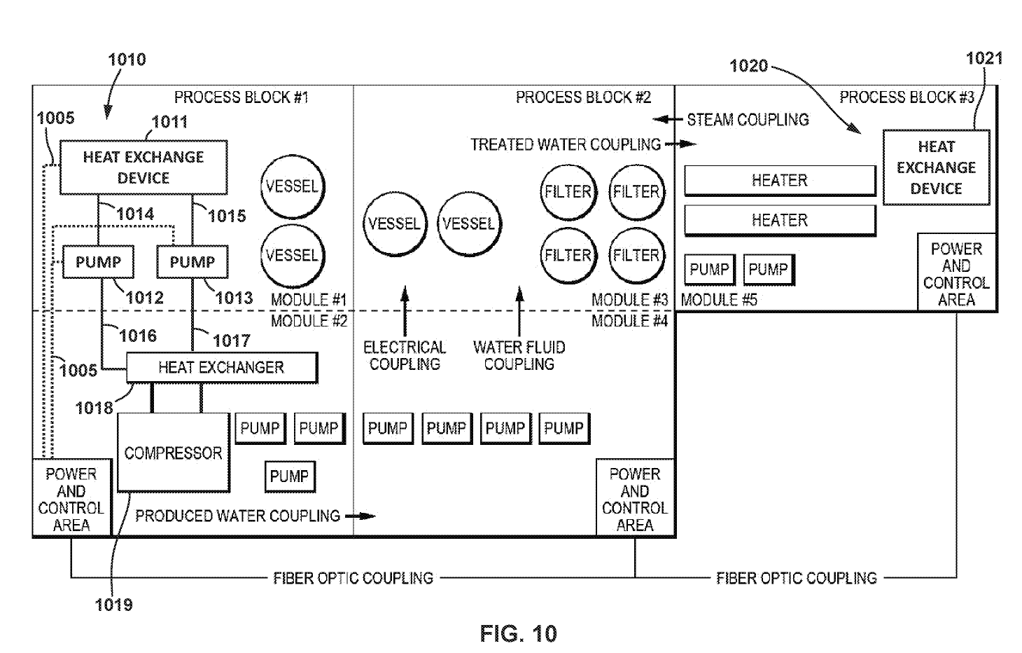

Referring now to FIG. 10, another 3rd Gen Modular facility including three process blocks (process blocks #1, #2, and #3) is shown. The 3rd Gen Modular facility of FIG. 10 is similar to the processing facility of FIG. 4, and thus, like components are the same as that described above for the 3rd Gen Modular facility of FIG. 4. However, the facility of FIG. 10 more particularly shows the distributed cooling systems of process blocks #1 and #3. In this embodiment, process block #2 does not include a distributed cooling system, as it should be appreciated that not every process block of a 3rd Gen modular processing facility needs to include its own individual distributed cooling system as described herein. Rather, in some embodiments, one of more process blocks (e.g., process block #2 in FIG. 10) has no need for an individual cooling system, and thus, does not include such a system.

In the embodiment of FIG. 10, process block #1 includes a cooling system 1010 that includes a heat exchange device 1011, a pair of pumps or either 1012 or 1013, and a plurality of fluid flow lines 1014, 1015, 1016, 1017 for circulating a first cooling fluid within process block #1. In this embodiment, heat exchange device 1011 includes one or more evaporative cooling towers. During operation, a cooling fluid (in this case water) is routed from heat exchange device, through line 1015 to and through pump 1013 to a heat exchanger 1018 arranged to exchange heat with a lubrication oil flowing through the bearings of an adjacent compressor 1019 (which may be compressing process fluid or some other auxiliary fluid within the process block #1). After exchanging heat with the lubrication oil in heat exchanger 1018, the now warm or hot cooling fluid is then routed through line 1016, pump 1012, and line 1014, and into heat exchange device 1011 (which again in this embodiment is an evaporative cooling tower), where the hot cooling fluid may exchange heat with the surrounding air/environment. Thereafter, the now cooled cooling fluid is recirculated back through lines 1015 and pump 1013 to heat exchanger 1018 to repeat the cooling process. During these operations, power (e.g., electrical power) is provided to cooling system 1010 (e.g., heat exchange device 1011, pumps 1012, 1013) through conductors 1005. For example, electric motors (not specifically shown) for driving pumps 102, 103 and/or fans within the heat exchange device (which is an evaporative cooling tower in this embodiment) are energized with electricity supplied via conductors 1005 (e.g., electric power cables) from the power and control area within process block #1.

In addition, in the embodiment of FIG. 10, process block #3 includes a cooling system 1020 that includes a heat exchange device 1021 for exchanging heat with a cooling fluid. Further details of cooling system 1020 are not shown in FIG. 10 so as not to unduly complicate the figure. However, in this embodiment, it should be appreciated that cooling system 1020 circulates a different cooling fluid from that circulated in cooling system 1010 at a different pressure from the cooling fluid circulated in cooling system 1010. For example, the cooling fluid of cooling system 1020 is glycol and is circulated at a pressure that is less than the cooling fluid (which is water in this embodiment) of cooling system 1010. In addition, in this embodiment, heat exchange device 1021 is different than the heat exchange device 1011 of cooling system 1010. Specifically, while heat exchange device 1011 of cooling system 1010 is an evaporative cooling tower in this embodiment, heat exchange device 1021 is a plate and frame heat exchanger. The differences in cooling fluid type and pressures as well as the difference in heat exchange device type are chosen to tailor design each cooling system 1010, 1020 for the needs of the corresponding process block (i.e., process blocks #1 and #3, respectively), such as for the specific reasons previously described above.

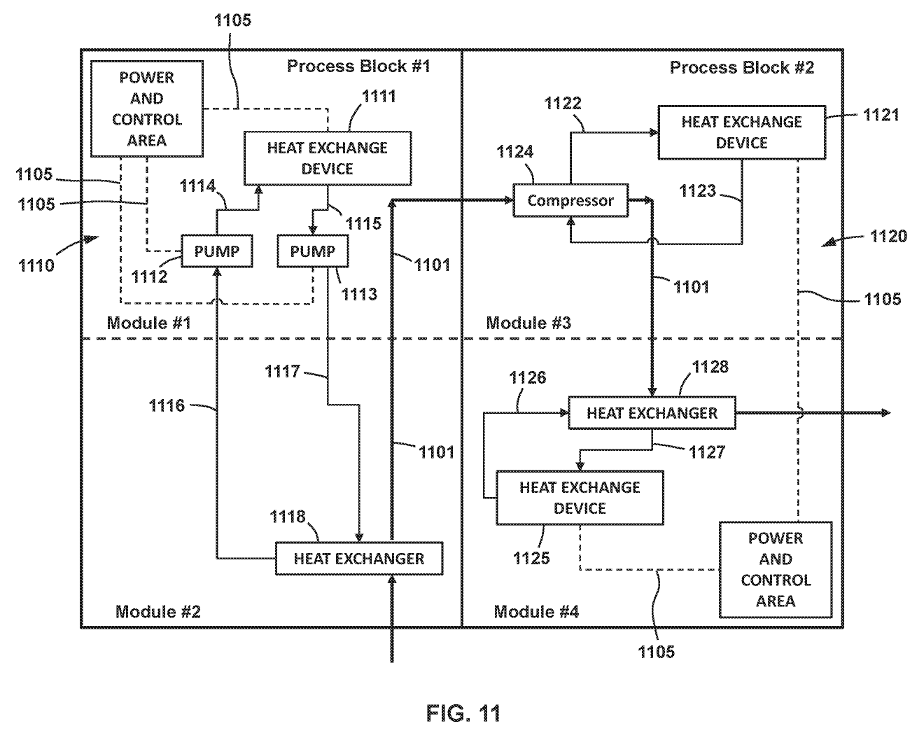

Referring now to FIG. 11, another 3rd Gen modular processing facility is shown that includes two process blocks (process blocks #1 and #2). In this embodiment, each process blocks #1, #2 includes its own distributed cooling system 1110, 1120, respectively. In addition, process blocks include a process flow line 1101 routed through each of the process blocks. Specifically, in this embodiment, each process block (i.e., process blocks #1, #2) includes a pair of modules (e.g., module #1, module #2 within process block #1 and module #3, module #4 within process block #2), and process flow line 1101 routes through each of modules #1, #2, #3, #4. In this embodiment, process flow line 1101 carries a main process fluid that is undergoing physical and chemical processing at the process facility. For example, in some embodiments, the process facility of FIG. 11 is an oil refinery (or a portion thereof), and the process flow line 1101 carries crude, refined, or partially refined oil or oil products (e.g., gasoline) therethrough. It should be appreciated that only some of the equipment within process blocks #1, #2 is shown in FIG. 11 to highlight the interaction of cooling systems 1110, 1120, and thus, other pieces of equipment may be included in process blocks #1, #2 that are not specifically shown.

Cooling system 1110 includes a heat exchange device 1111, a pair of pumps or either 1112 or 1113, a heat exchanger 1118, and a plurality of fluid flow lines 1114, 1115, 1116, 1117. As previously described, heat exchange device 1111 may comprise any one or more of a evaporative cooling tower, a heat exchanger, a refrigeration cycle cooling system, a fin fan cooler, etc. In this embodiment, heat exchange device 1111 comprises an evaporative cooling tower that is configured to exchange heat from a first cooling fluid (e.g., in this case water) and a surrounding environment or atmosphere. During operations, the first cooling fluid is routed via pump 1113 through lines 1115, 1117 to a heat exchanger 1118, which may comprise a shell and tube heat exchanger or another type of heat exchanger. In this embodiment, heat exchanger 1118 is configured to exchange heat between the process fluid flowing in line 1101 within module #2 to thereby cool the process fluid. The now hot or warm cooling fluid is then expelled from heat exchanger 1118 and is routed back to heat exchange device 1111 via lines 1116, 1114 and pump 1112 (which again in this embodiment is an evaporative cooling tower), where the hot cooling fluid may exchange heat with the surrounding air/environment. Thus, in this embodiment, cooling system 1110 is primarily utilized to cool process fluid flowing within line 1101 as it routes through modules #1 and #2 within process block #1.

Referring still to FIG. 11, cooling system 1120 includes a first heat exchange device 1121 disposed within module #3 and a second heat exchange device 1125 disposed within module #4. In this embodiment, first and second heat exchange devices 1121, 1125 are different from one another. Specifically, in this embodiment, first heat exchange device 1121 comprises a shell and tube heat exchanger, and second heat exchange device 1125 comprises a fin fan air cooler (or a plurality of fin fan air coolers).

A pair of lines 1122, 1123 extends between first heat exchange device 1121 and a compressor 1124 that is disposed along line 1101 within module #3 of process block #2 and is configured to compress the process fluid flowing within line 1101. In this embodiment, heat exchange device 1121 cools a cooling fluid that is routed through lines 1122, 1123 to cool the process fluid as it flows between stages of compressor 1124. In other embodiment, the cooling fluid routed through lines 1122, 1123 may cool lubrication oil that is supplied to one or more of the bearings of compressor 1124 (e.g., in the manner described above for cooling system 1010 of FIG. 10). It should be appreciated that in at least some embodiments, pumps (not shown) may be disposed along one or both of lines 1122, 1123 to facilitate the flow of fluid between heat exchange device 1121 and compressor 1124. Such pumps would be similar to those shown for cooling system 1110 (e.g., pumps 1112, 1113) and/or the pumps shown for cooling system 1010 in FIG. 10 (e.g., pumps 1012, 1013). Heat exchange device 1121, which is a heat exchanger in this embodiment as previously described, is configured to exchange heat with the cooling fluid routed through lines 1122, 1123 and another fluid, such as, for example, water, glycol, oil, a refrigerant, etc.

A pair of lines 1126, 1127 extends between heat exchange device 1125 and a heat exchanger 1128 disposed along line 1101 within module #4 of process block #2. Heat exchanger 1128 may be of any conventional design and is configured to cool the process fluid flowing within line 1101 after it is expelled from compressor 1124 in module #3. Thus, a cooling fluid is circulated from heat exchange device 1125 to heat exchanger 1126 via line 1126 to exchange heat with the process fluid. Then, the now warm cooling fluid is routed back to heat exchange device 1125 where it exchanges heat with the surrounding environment (e.g., through forced or induced air draft across a plurality of tubes as per the potential designs of a fin fan air cooler). It should be appreciated that in at least some embodiments, pumps (not shown) may be disposed along one or both of lines 1126, 1127 to facilitate the flow of fluid between heat exchange device 1125 and heat exchanger 1128. Such pumps would be similar to those shown for cooling system 1110 (e.g., pumps 1112, 1113) and/or the pumps shown for cooling system 1010 in FIG. 10 (e.g., pumps 1012, 1013).

For each of the cooling systems 1110, 1120, the operative equipment for facilitating flow of cooling fluid through lines 1114, 1115, 1116, 1117, 1122, 1123, 1126, 1127 and for operating heat exchange devices 1111, 1112, 1125 (e.g., various electric motors, valves, pumps, fans, refrigeration systems etc.) is energized via power routed from the individual power and control areas and associated conductors 1105 of each corresponding process block (e.g., process blocks #1, #2). Specifically, the operative equipment (e.g., pumps 1112, 1113 and heat exchange device 1111) for operating cooling system 1110 is energized via the power and control area (i.e., the distributed E+I) within process block #1, and the operative equipment (e.g., heat exchange devices 1121, 1125, pumps, etc.) for operating cooling system 1120 is energized via the power and control area (i.e., the distributed E+I) within process block #2.

In addition, in this embodiment, the cooling fluid routed through lines 1114, 1115, 1116, 1117 within cooling system 1110 is different than the cooling fluids routed through lines 1122, 1123, 1126, 1127 within cooling system 1120. Moreover, the cooling fluid routed through lines 1122, 1123 in cooling system 1120 is different from the cooling fluid routed through lines 1126, 1127 in cooling system 1120. For example, the cooling fluid routed through lines 1114, 1115, 1116, 1117 is one of water, glycol, oil, air or other gases, a refrigerant, the cooling fluid routed through lines 1122, 1123 is another different one of water, glycol, oil, air or other gases, a refrigerant, and the cooling fluid routed through lines 1126, 1127 is still another different one of water, glycol, oil, air or other gases, a refrigerant.

Further, because the pressure of the process fluid in line 1101 is different in process blocks #1 and #2 (e.g., due at least to compressor 1124), the pressure of the cooling fluids in cooling system 1110 is different from the pressures of the cooling fluids in cooling system 1120. Specifically, as previously described, in at least some instances, it is desirable to circulate the cooling fluid within the corresponding cooling system at a pressure which is above the fluid which the cooling fluid is exchanging heat with (e.g., in this case, the process fluid) so that a leak or failure in a fluid barrier between the cooling fluid and cooled fluid results in a leak of cooling fluid into the cooled fluid rather than a leak of the cooled fluid (i.e., in this case the process fluid) into the cooling fluid. Thus, because the pressure of the process fluid routed through line 1101 is higher in process block #2 than in process block #1, the pressure of the cooling fluid in cooling system 1110 is lower than the pressures of the cooling fluids in cooling system 1120. Also, because the cooling fluid within lines 1126, 1127 is downstream of compressor 1124, the pressure of cooling fluid in lines 1126, 1127 may be greater than the pressure of the cooling fluid in lines 1122, 1123.

Further, in this embodiment, the cooling requirements of the process fluid in line 1101 are different in process block #1 and #2. Specifically, in this embodiment, it is desired that the process fluid be at a greater temperature downstream of compressor 1124 and heat exchanger 1128 than upstream of compressor within process block #1. Therefore, the heat dissipation rates of the heat exchange device 1111 is different (in this case greater) than the heat dissipation rate of heat exchange device 1121 and/or heat exchange device 1125. Thus, it is possible to specifically design cooling system 1110 to carry a first level of cooling within process block #1 and to specifically design cooling system 1120 to carry out a second and different level of cooling within process block #2. As a result, the energy required to operate cooling systems 1110 and 1120 is tailor made to fit the desired processing needs for process blocks #1, #2 (i.e., such that the processing facility of FIG. 11 may operate more efficiently than if a common, centralized cooling system were utilized for both process blocks #1, #2).

Still further, it should be appreciated that each of the lines 1114, 1115, 1116, 1117 of cooling system 1110, and each of the lines 1122, 1123, 1126, 1127 of cooling system 1120 are not routed through interconnecting piperacks and are instead routed directly between the connected equipment (e.g., heat exchange devices 1111, 1121, 1125, pumps 1112, 1113, compressor 1124, heat exchangers 1118, 1128, etc.). As described above, however, makeup lines (not shown) for supplying make up cooling fluids to cooling systems 1110, 1120, 1128 may extend from a common piping spine (not shown) that may be similar to that shown in FIG. 9.

It should be apparent to those skilled in the art that many more modifications besides those already described are possible without departing from the concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, utilized, or combined with other elements, components, or steps that are not expressly referenced. Where the specification claims refer to at least one of something selected from the group consisting of A, B, C . . . and N, the text should be interpreted as requiring only one element from the group, not A plus N, or B plus N, etc.

Accordingly, the scope of protection is not limited by the description set out above, but is defined by the claims which follow, that scope including all equivalents of the subject matter of the claims. In the claims, any designation of a claim as depending from a range of claims (for example #-##) would indicate that the claim is a multiple dependent claim based on any claim in the range (e.g. dependent on claim # or claim ## or any claim therebetween). Each and every claim is incorporated as further disclosure into the specification, and the claims are embodiment(s) of the present invention(s). Furthermore, any advantages and features described above may relate to specific embodiments, but shall not limit the application of such issued claims to processes and structures accomplishing any or all of the above advantages or having any or all of the above features.

Additionally, the section headings used herein are provided for consistency with the suggestions under 37 C.F.R. 1.77 or to otherwise provide organizational cues. These headings shall not limit or characterize the invention(s) set out in any claims that may issue from this disclosure. Specifically and by way of example, although the headings might refer to a “Field,” the claims should not be limited by the language chosen under this heading to describe the so-called field. Further, a description of a technology in the “Background” is not to be construed as an admission that certain technology is prior art to any invention(s) in this disclosure. Neither is the “Summary” to be considered as a limiting characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of the claims shall be considered on their own merits in light of this disclosure, but should not be constrained by the headings set forth herein.

Use of broader terms such as “comprises”, “includes”, and “having” should be understood to provide support for narrower terms such as “consisting of”, “consisting essentially of”, and “comprised substantially of”. Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

1. A processing facility, comprising:
a first process block configured to carry out a first process, the first process block comprising:
a plurality of first modules fluidly coupled to one another; and
a first cooling system configured to circulate a first cooling fluid within the first process block; and
a second process block configured to carry out a second process that is different from the first process, the second process block comprising:
a plurality of second modules fluidly coupled to one another;
a second cooling system configured to circulate a second cooling fluid within the second process block;
wherein the first cooling system has a first heat dissipation rate, the second cooling system has a second heat dissipation rate, and the first heat dissipation rate is different from the second heat dissipation rate.

2. The processing facility of claim 1, wherein the first cooling fluid is different from the second cooling fluid.

3. The processing facility of claim 2, wherein the first cooling fluid is one of water, glycol, oil, gas, and refrigerant, and wherein the second cooling fluid is another of water, glycol, oil, gas, and refrigerant.

4. The processing facility of claim 1, wherein the first cooling system is an evaporative style cooling system, and wherein the second cooling system is a dry cooling system.

5. The processing facility of claim 1, wherein the first cooling system comprises a cooling tower; and
wherein the second cooling comprises a plate and frame heat exchanger.

6. The processing facility of claim 1, wherein the first cooling system is configured to circulate the first cooling fluid at a first pressure; and
wherein the second cooling system is configured to circulate the second cooling fluid at a second pressure that is different from the first pressure.

7. The processing facility of claim 6, wherein the first process block circulates a first process fluid at a third pressure and wherein the second process block circulates a second process fluid at a fourth pressure;
wherein first pressure is higher than the third pressure; and
wherein the second pressure higher than the fourth pressure.

8. The processing facility of claim 1, wherein the first cooling system includes a first plurality of conduits configured to circulate the first cooling fluid within the first process block;
wherein the second cooling system includes a second plurality of conduits configured to circulate the second cooling fluid within the second process block;
wherein the first plurality of conduits and the second plurality of conduits are not run through an interconnecting piperack.

9. The processing facility of claim 8, further comprising a piping spine extending through each of the first plurality modules and the second plurality of modules, wherein the piping spine includes a first header line configured to supply the first cooling fluid to the first cooling system.

10. The processing facility of claim 9, wherein the piping spine includes a second header line configured to supply the second cooling fluid to the second cooling system.

11. The processing facility of claim 1, wherein the first process block has a first electrical and instrumentation (E+I) distribution including one or more conductors configured to conduct at least one of electricity and control signals to equipment within the first process block;
wherein the second process block has a second E+I distribution including one or more conductors configured to conduct at least one of electricity and control signals to equipment within the second process block; and
wherein the first cooling system and the first E+I distribution of the first process block are configured to be pre-commissioned at a construction facility prior to installation of the first process block at an ultimate installation site for the processing facility; and
wherein the second cooling system and the second E+I distribution of the second process block are configured to be pre-commissioned at the construction facility prior to installation of the second process block at the installation site.

12. The processing facility of claim 1,
wherein the first cooling system comprises:
a first heat exchange device configured to transfer heat from the first cooling fluid to a surrounding environment; and
a first plurality of fluid conduits coupled to the first heat exchange device and configured to circulate the first cooling fluid between the first heat exchange device and equipment within and throughout the first process block; and
wherein the second cooling system comprises:
a second heat exchange device configured to transfer heat from the second cooling fluid to a surrounding environment; and
a second plurality of fluid conduits coupled to the second heat exchange device and configured to circulate the second cooling fluid between the second heat exchange device and equipment within and through the second process block.

13. The processing facility of claim 12, wherein the first heat exchange device is disposed one of along a peripheral edge and atop of one of the first plurality of modules; and
wherein the second heat exchange device is disposed one of along a peripheral edge and atop of one of the second plurality of modules.

14. A processing facility, comprising:
a first process block configured to carry out a first process, the first process block comprising:
a plurality of first modules fluidly coupled to one another; and
a first cooling system configured to circulate a first cooling fluid within the first process block, the first cooling system including a first plurality of conduits and a first heat exchange device;
wherein the first plurality of conduits are configured to circulate first cooling fluid between the first heat exchange device and equipment within the first process block; and
a second process block configured to carry out a second process, the second process block comprising:
a plurality of second modules fluidly coupled to one another; and
a second cooling system configured to circulate a second cooling fluid within the second process block, the second cooling system including a second plurality of conduits and a second heat exchange device;
wherein the second plurality of conduits are configured to circulate the second cooling fluid between the second heat exchange device and equipment within the second process block;
wherein the first plurality of conduits and the second plurality of conduits are entirely disposed within an outer periphery of the first process block and the second process block, respectively, and are not run through an interconnecting piperack.

15. The processing facility of claim 14, wherein the first process block has a first electrical and instrumentation (E+I) distribution including one or more conductors configured to conduct at least one of electricity and control signals to equipment within the first process block;
wherein the second process block has a second E+I distribution including one or more conductors configured to conduct at least one of electricity and control signals to equipment within the second process block; and
wherein the first cooling system and the first E+I distribution of the first process block are configured to be pre-commissioned at a construction facility prior to installation of the first process block at an ultimate installation site for the processing facility; and
wherein the second cooling system and the second E+I distribution of the second process block are configured to be pre-commissioned at the construction facility prior to installation of the second process block at the installation site.

16. The processing facility of claim 14, wherein the first cooling system has a first heat dissipation rate;
wherein the second cooling system has a second heat dissipation rate; and
wherein the first heat dissipation rate is different from the second heat dissipation rate.

17. The processing facility of claim 14, wherein the first cooling fluid is different from the second cooling fluid.

18. The processing facility of claim 14, wherein the first cooling system is configured to circulate the first cooling fluid at a first pressure; and
wherein the second cooling system is configured to circulate the second cooling fluid at a second pressure that is different from the first pressure.

19. The processing facility of claim 14, wherein the first cooling system is configured to circulate the first cooling fluid at a first pressure; and
wherein the second cooling system is configured to circulate the second cooling fluid at a second pressure that is different from the first pressure.

20. A processing facility, comprising:
a first process block configured to carry out a first process, the first process block comprising:
a plurality of first modules fluidly coupled to one another; and
a first cooling system configured to circulate a first cooling fluid within the first process block, the first cooling system including a first plurality of conduits and a first heat exchange device;
wherein the first plurality of conduits are configured to circulate fluid between the first heat exchange device and equipment within the first process block; and
wherein the first cooling system has a first heat dissipation rate; and
a second process block configured to carry out a second process that is different from the first process, the second process block comprising:
a plurality of second modules fluidly coupled to one another;
a second cooling system configured to circulate a second cooling fluid within the second process block, the second cooling system including a second plurality of conduits and a second heat exchange device;
wherein the second plurality of conduits are configured to circulate fluid between the second heat exchange device and equipment within the second process block;
wherein the second cooling system has a second heat dissipation rate that is different from the first heat dissipation rate; and
wherein the first plurality of conduits and the second plurality of conduits are not run through an interconnecting piperack.
